(19) United States
(12) Patent Application Publication
(10) Pub. No.: US 2026/0214819 A1
(43) Pub. Date: Jul. 23, 2026

(54) 2832-1432PUS1

(71) Applicant: LG ELECTRONICS INC., Seoul (KR)

(72) Inventors: Seunggyu KANG, Seoul (KR); Jonggil PYO, Seoul (KR); Jaehun LEE, Seoul (KR)

(73) Assignee: LG ELECTRONICS INC., Seoul (KR)

(21) Appl. No.: 19/139,217

(22) PCT Filed: Dec. 16, 2022
(86) PCT No.: PCT/KR2022/020644

§ 371 Date: Jun. 13, 2025

(51) Int. Cl. H05K 5/02; H05K 5/03

(52) U.S. Cl. CPC H05K 5/0217; H05K 5/03

(57) ABSTRACT

A display device is provided. The display device includes: a display panel configured to display an image and having light transparency; a frame located adjacent to a side edge of the display panel; a transparent panel facing the display panel and coupled to the frame; a light-transmissive back cover opposite the transparent panel with respect to the display panel, and facing the display panel; and a cover frame fixed to the back cover and coupled to the frame.

### TECHNICAL FIELD

The present description relates to a display device. More particularly, the present disclosure relates to a display device including a transparent display panel.

### BACKGROUND ART

With the development of the information society, there have been growing demands for various types of display devices, and in order to meet these demands, various display devices, such as a liquid crystal display (LCD) device, a Plasma Display Panel (PDP), an electroluminescent display (ELD), a vacuum fluorescent display (VFD), an organic light emitting diode (OLED), etc., have been studied and used recently.

Among them, the LCD panel includes a TFT substrate and a color substrate which are positioned opposite each other with a liquid crystal layer interposed therebetween, and displays images by using light provided by a backlight unit. Further, the OLED panel may display images by using a self-emitting organic layer deposited on a substrate on which transparent electrodes are formed.

Recently, many studies are being conducted on a transparent display panel capable of not only displaying images to a user, but also allowing the user to see behind the display panel.

### DISCLOSURE OF INVENTION

### Technical Problem

It is an objective of the present disclosure to solve the above and other problems.

It is another objective of the present disclosure to provide a display device including a transparent display panel.

It is yet another objective of the present disclosure to provide a structure for opening and closing the rear of a transparent display panel.

It is yet another objective of the present disclosure to provide a frame structure to which a transparent display panel is coupled.

### Solution to Problem

In accordance with an aspect of the present disclosure, the above and other objectives can be accomplished by providing a display device including: a display panel configured to display an image and having light transparency; a frame located adjacent to a side edge of the display panel; a transparent panel facing the display panel and coupled to the frame; a light-transmissive back cover opposite the transparent panel with respect to the display panel, and facing the display panel; and a cover frame fixed to the back cover and coupled to the frame.

### Advantageous Effects of Disclosure

The display device according to the present disclosure has the following effects.

According to at least one of the embodiments of the present disclosure, a display device including a transparent display panel may be provided.

According to at least one of the embodiments of the present disclosure, a structure for opening and closing the rear of a transparent display panel may be provided.

According to at least one of the embodiments of the present disclosure, a frame structure to which a transparent display panel is coupled may be provided.

Further scope of applicability of the present disclosure will become apparent from the detailed description given hereinafter. However, it should be understood that the detailed description and specific examples, while indicating preferred embodiments of the present disclosure, are given by illustration only, since various changes and modifications within the spirit and scope of the present disclosure will become apparent to those skilled in the art from this detailed description.

### BRIEF DESCRIPTION OF DRAWINGS

FIGS. 1 to 35 are diagrams illustrating examples of a display device according to embodiments of the present disclosure.

### MODE OF DISCLOSURE

Hereinafter, the present disclosure will be described in detail with reference to the accompanying drawings, in which the same reference numerals are used throughout the drawings to designate the same or similar components, and a redundant description thereof will be omitted.

The suffixes, such as “module” and “unit,” for elements used in the following description are given simply in view of the ease of the description, and do not have a distinguishing meaning or role.

In addition, it will be noted that a detailed description of known arts will be omitted if it is determined that the detailed description of the known arts can obscure the embodiments of the present disclosure. Further, the accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that, although the terms first, second, etc., may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A singular representation may include a plural representation unless context clearly indicates otherwise.

It should be understood that the terms “comprise,” “include,” “have,” etc. when used in this specification, specify the presence of stated features, integers, steps, operations, elements, components, or combinations thereof but do not preclude the presence or addition of one or more other features, integers, steps, operations, elements, components, or combinations thereof.

References to directions, such as up (U), down (D), left (Le), right (Ri), front (F), and rear (R), shown in the drawings are provided merely for convenience of explanation and are not intended to limit the scope of the present disclosure.

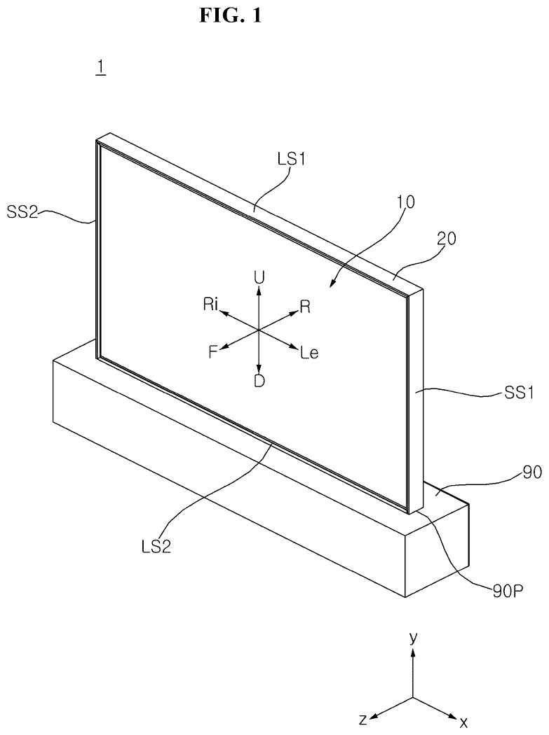

Referring to FIG. 1, a display device 1 may include a display 10, a side frame 20, and a housing 90. The display 10 may display an image. The side frame 20 may extend along the perimeter of the display 10. The housing 90 may be positioned beneath the display 10 and the side frame 20. Alternatively, the housing 90 may be positioned on the upper side, left side, or lower side of the display 10 and the side frame 20.

The display 10 may include a first long side LS1, a second long side LS2 opposite to the first long side LS1, a first short side SS1 adjacent to the first and the second long sides LS1 and LS2, and a second short side SS2 opposite to the first short side SS1. Meanwhile, for convenience of explanation, it is illustrated and described that the first and second long sides LS1 and LS2 are longer than the first and second short sides SS1 and SS2, but it is also possible that the lengths of the first and second long sides LS1 and LS2 may be approximately equal to or longer than the lengths of the first and second short sides SS1 and SS2.

The long sides LS1 and LS2 and the short sides SS1 and SS2 of the display 10 may be formed on the side frame 20.

A direction parallel to the long sides LS1 and LS2 of the display 10 may be referred to as a left-right direction. A direction parallel to the short sides SS1 and SS2 of the display 10 may be referred to as an up-down direction. A direction perpendicular to the long sides LS1 and LS2 and the short sides SS1 and SS2 of the display 10 may be referred to as a front-rear direction.

A side on which the display 10 displays an image may be referred to as a front side F, z, and a side opposite thereto may be referred to as a rear side R. The first short side SS1 may be referred to as a left side Le, x, and the second short side SS2 may be referred to as a right side Ri. The first long side LS1 may be referred to as an upper side U, y, and the second long side LS2 may be referred to as a lower side D.

Hereinafter, an Organic Light Emitting Diode (OLED) display panel will be described as an example, but the display panel applicable to the present disclosure is not limited thereto.

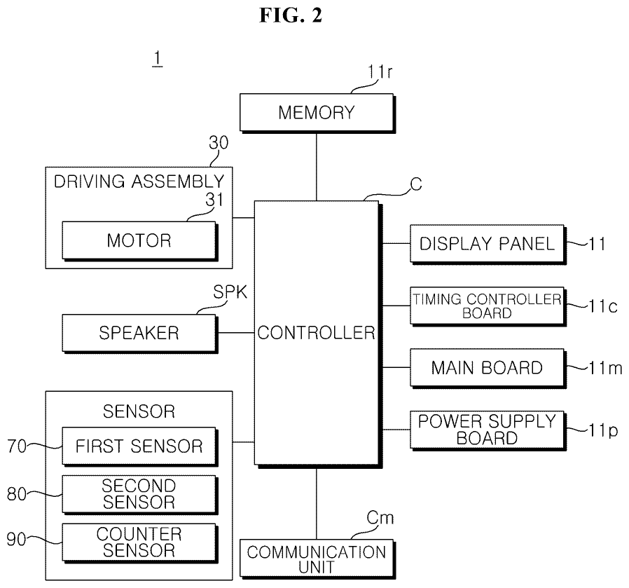

Referring to FIG. 2, a controller C of the display device 1 may control the operation of the display device 1. The controller C may be electrically connected to components of the display device 1.

A display panel 11, a main board 11m, a power supply board 11p, and a timing controller board 11c may be installed in an inner space of the housing 90 and may be electrically connected to the controller C. The main board 11m may control the display device 1. The controller C may be implemented as the main board 11m or may be a superordinate control unit that controls the main board 11m and the like. The power supply board 11p may provide power to each component of the display device 1. The timing controller board 11c may provide an image signal to the display panel 11.

A motor 31 of a driving assembly 30 may be electrically connected to the controller C. The controller C may control the operation of the motor 31. The controller C may control the rotation amount (rotation angle), rotation direction, and rotation speed of the motor 31. For example, the motor 31 may be a step motor.

A speaker SPK may be installed in the inner space of the housing 90. The speaker SPK may be electrically connected to the controller C. A speaker hole (not shown) may be formed in the housing 90, and the speaker SPK may provide sound through the speaker hole (not shown).

A communication unit Cm may transmit information of the display device 1 to an external device or transmit various types of information or signals from an external device to the display device 1. The communication unit Cm may perform communication with a remote control device, a portable terminal, a wired/wireless router, or other communication infrastructure (e.g., a server), etc. For example, the communication unit Cm may perform wireless communication with an external device by using a communication technology such as IEEE 802.11 WLAN, IEEE 802.15 WPAN, UWB, Wi-Fi, Zigbee, Z-wave, Blue-Tooth, and the like.

A memory 11r may be electrically connected to the controller C. The memory 11r may store basic data (e.g., basic specification information for each configuration of the display device, such as display resolution, brightness, sound output value, etc.) for the display device 1, data and programs for controlling the operation of the display device 1, data input from the outside, or data processed by the controller C, or the like. For example, the memory 11r may store information related to the operation of the motor 31. For example, the memory 11r may include ROM, RAM, EPROM, a flash drive, a hard drive, or the like. For example, the memory 11r may be classified as a sub-component of the controller C.

Meanwhile, a first sensor 70, a second sensor 80, and a counter sensor 90 which will be described later may be electrically connected to the controller C.

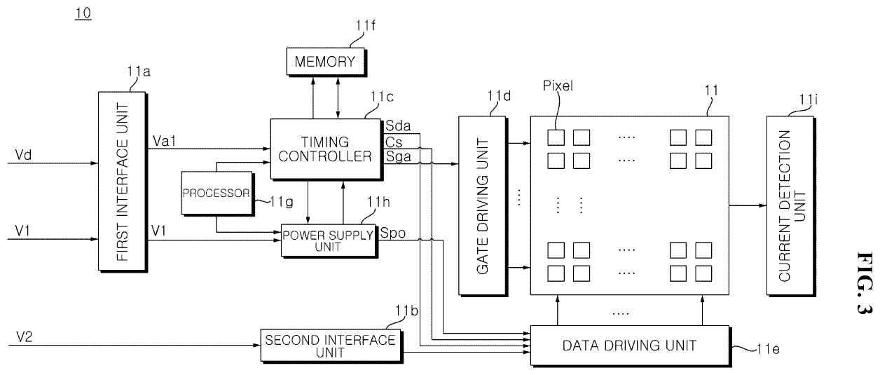

Referring to FIG. 3, the display 10 may include a display panel 11, a first interface unit 11a, a second interface unit 11b, a timing controller 11c, a gate driving unit 11d, a data driving unit 11e, a memory 11f, a processor 11g, a power supply unit 11h, and a current detection unit 11i. The display panel 11 may be an Organic Light Emitting Diode (OLED) panel.

The first interface unit 11a may receive first direct current (DC) power V1 from a power supply unit external to the display 10, and the first DC power V1 may be supplied for the operation of the power supply unit 11h and the timing controller 11c.

The second interface unit 11b may receive second DC power V2 from a power supply unit external to the display 10, and the second DC power V2 may be supplied to the data driving unit 11e.

The timing controller 11c may output a data driving signal Sda and a gate driving signal Sga based on an image signal Vd input to the first interface unit 11a. For example, the first interface unit 11a may convert the image signal Vd and output a converted image signal Va1, and the timing controller 11c may output a data driving signal Sda and a gate driving signal Sga based on the converted image signal Va1. The data driving signal Sda may be a driving signal for subpixels of the display panel 11. In addition, the timing controller 11c may further output a control signal Cs to the data driving unit 11e.

The gate driving unit 11d and the data driving unit 11e may provide a scanning signal and an image signal to the display panel 11 through a gate line GL and a data line DL according to the gate driving signal Sga and the data driving signal Sda of the timing controller 11c. Accordingly, the display panel 11 may display an image.

The power supply unit 11h may provide various types of power to the gate driving unit 11d, the data driving unit 11e, the timing controller 11c, and the like.

The current detection unit 11i may detect the current flowing in the subpixel of the display panel 11. The detected current may be input to the processor 11g for calculation of cumulative current. The calculated cumulative current may be stored in the memory 11f.

The processor 11g may perform various controls within the display 10. For example, the processor 11g may control the gate driving unit 11d, the data driving unit 11e, the timing controller 11c, and the like.

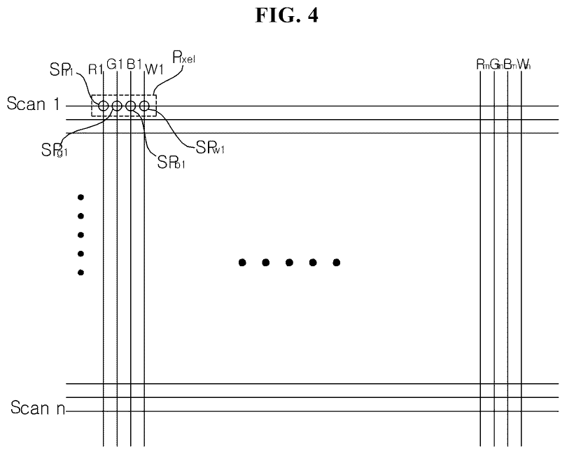

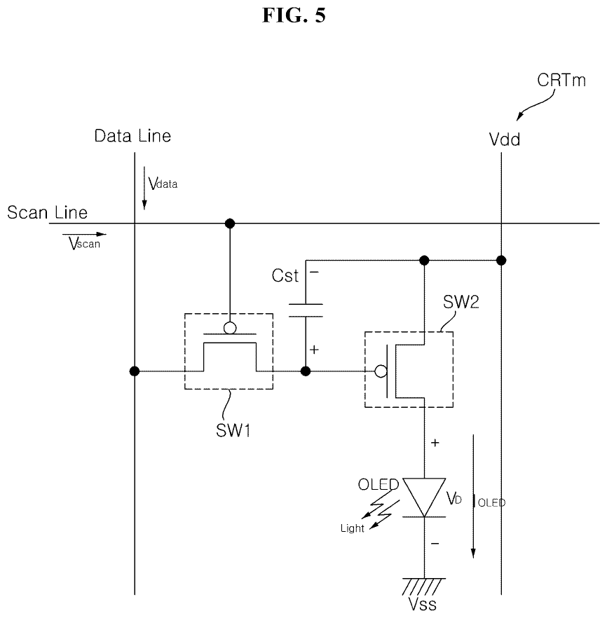

Referring to FIGS. 4 and 5, the display panel 11 may include a plurality of scan lines Scan 1 to Scan n and a plurality of data lines R1, G1, B1, W1 to Rm, Gm, Bm, Wm. The plurality of data lines R1, G1, B1, W1 to Rm, Gm, Bm, Wm may intersect with the plurality of scan lines Scan 1 to Scan n. A subpixel may be defined in an intersection area of the scan line and the data line. A pixel may be a hold type element that continuously emits light in an organic light-emitting layer (OLED) during a unit frame image after a scan signal is applied. For example, a pixel may include RGBW subpixels. In another example, a pixel may include RGB subpixels.

The circuit CRTm of the subpixel may be an active type, and may include a scan switching element SW1, a storage capacitor Cst, a driving switching element SW2, and an organic light-emitting layer OLED.

The scan switching element SW1 may be turned on according to a scan signal Vscan input from the scan line. When the scan switching element SW1 is turned on, the scan switching element SW1 may transmit a data signal Vdata input from the data line to one end of the storage capacitor Cst or the gate terminal of the driving switching element SW2.

The storage capacitor Cst may be provided between the gate terminal and the source terminal of the driving switching element SW2, and may store a difference between the level of the data signal transmitted to one end of the storage capacitor Cst and the level of the DC power VDD transmitted to the other end of the storage capacitor Cst.

For example, if the data signal has a different level according to a Pulse Amplitude Modulation (PAM) method, the power level stored in the storage capacitor Cst may vary according to the level difference of the data signal Vdata. In another example, if the data signal has a different pulse width according to a Pulse Width Modulation (PWM) method, the power level stored in the storage capacitor Cst may vary according to a difference in pulse width of the data signal Vdata.

The driving switching element SW2 may be turned on according to the power level stored in the storage capacitor Cst. When the driving switching element SW2 is turned on, a driving current IOLED proportional to the stored power level may flow to the organic light-emitting layer OLED. Accordingly, the organic light-emitting layer OLED may perform a light-emitting operation.

The organic light-emitting layer OLED may include an RGBW light-emitting layer EML corresponding to a subpixel, may include at least one of a hole injection layer HIL, a hole transport layer HTL, an electron transport layer ETL, or an electron injection layer EIL, and may also include a hole blocking layer HBL, or the like.

Meanwhile, FIG. 5 illustrates a p-type MOSFET as a scan switching element SW1 and a driving switching element SW2, but a switching element such as an n-type MOSFET, JFET, IGBT, or SIC may also be used.

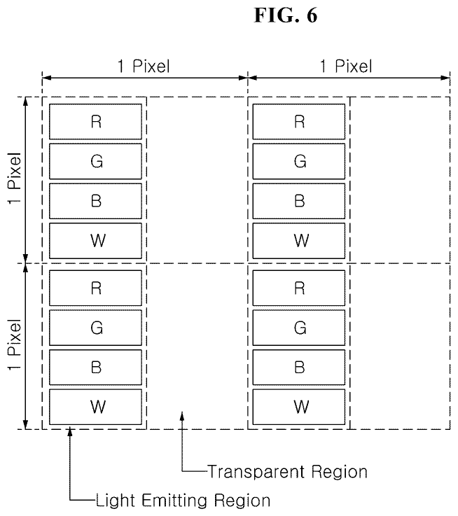

Referring to FIG. 6, a pixel may include a light emitting region and a transparent region. Red, Green, Blue, and White (RGBW) subpixels may be arranged vertically in the light emitting region, and the transparent region with no subpixels may be arranged next to the light emitting region.

Accordingly, the display panel 11 having a plurality of pixels may not only display an image but also transmit light. The display panel 11 may be referred to as a transparent display panel or a transparent OLED panel.

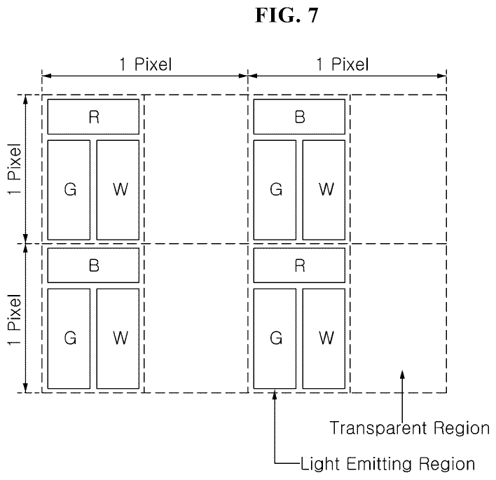

Referring to FIG. 7, a pixel may include a light emitting region and a transparent region. Red, Green and White (RGW) subpixels or Blue, Green and White (BGW) subpixels may be arranged next to each other in the light emitting region, and the transparent region with no subpixels may be arranged next to the light emitting region.

Accordingly, the display panel 11 having a plurality of pixels may not only display an image but also transmit light. The display panel 11 may be referred to as a transparent display panel or a transparent OLED panel.

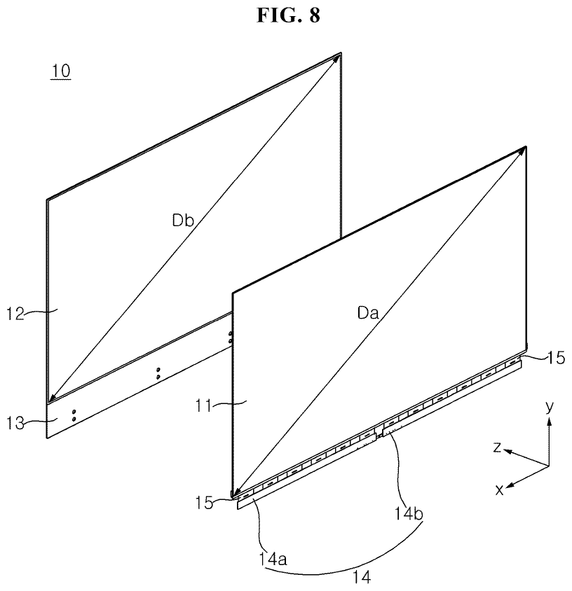

Referring to FIG. 8, the display panel 11 may output an image by dividing an image into a plurality of pixels and adjusting the color, brightness, and saturation for each pixel. The display panel 11 may be divided into an active area where an image is displayed and a de-active area where an image is not displayed. The display panel 11 may generate light corresponding to red (R), green (G), or blue (B) color in response to a control signal.

A source PCB 14 may be adjacent to the lower side of the display panel 11. The source PCB 14 may extend along the lower side of the display panel 11. The source PCB 14 may be electrically connected to the display panel 11 through a Chip On Film (COF) 15. The source PCB 14 may be electrically connected to the timing controller board 11c (see FIG. 2) through a cable (not shown) such as a Flexible Flat Cable (FFC).

The transparent panel 13 may be located in front of the display panel 11. The transparent panel 13 may be made of transparent glass. An adhesive film 12 may be located between the display panel 11 and the transparent panel 13, and may be coupled to the display panel 11 and the transparent panel 13. The adhesive film 12 may be an Optically Clear Adhesive (OCA) film.

In addition, the adhesive film 12 may cover at least a portion of the rear surface of the transparent panel 13. For example, one side of the adhesive film 12 may be located closer to the center of the display panel 11 than one side of the transparent panel 13 that corresponds thereto. For example, the upper side, left side, and right side of the adhesive film 12 may be respectively adjacent to the upper side, left side, and right side of the transparent panel 13, and the lower side of the adhesive film 12 may be spaced above the lower side of the transparent panel 13.

In addition, the size of the adhesive film 12 may correspond to the size of the display panel 11. For example, a diagonal length Db of the adhesive film 12 may be substantially equal to a diagonal length Da of the display panel 11. In another example, the diagonal length Db of the adhesive film 12 may be greater than the diagonal length Da of the display panel 11. In this case, a portion of the adhesive film 12 may be located along the perimeter of the display panel 11 on the outside of the display panel 11.

Meanwhile, the display panel 11, the adhesive film 12, and the transparent panel 13 may be referred to as the display 10.

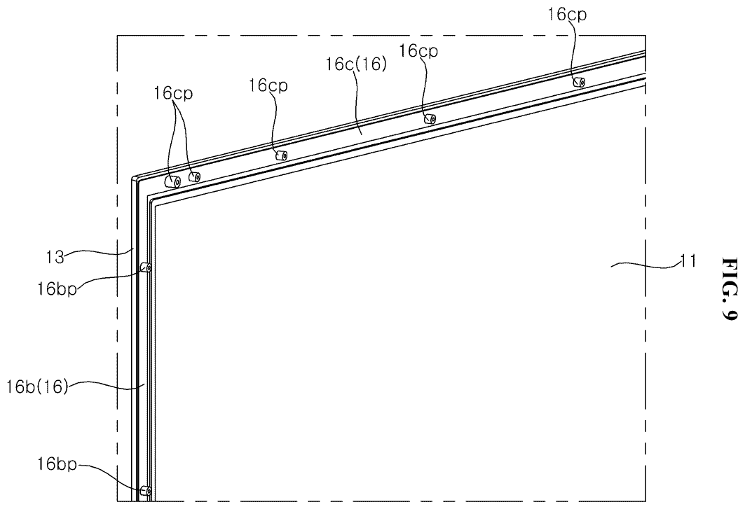

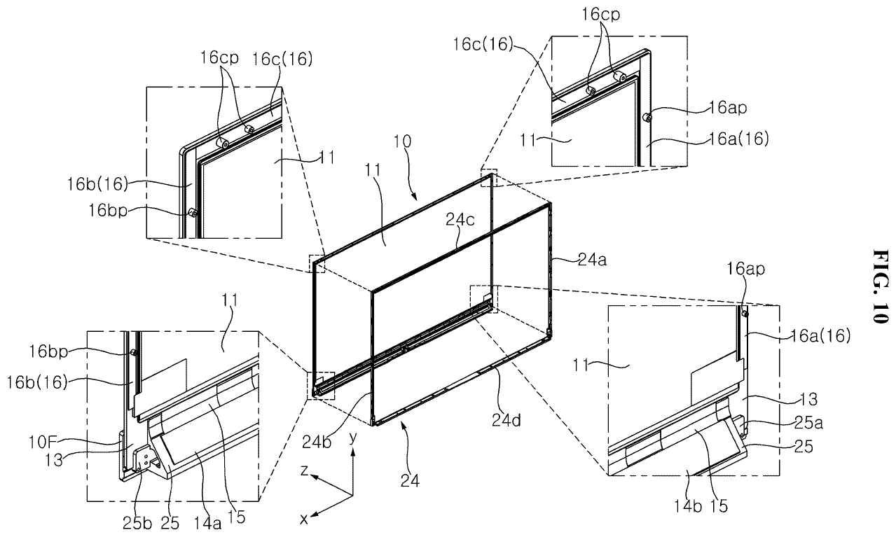

Referring to FIGS. 9 and 10, a fixing member 16 may be adjacent to the perimeter of the display panel 11 and may extend along the perimeter of the display panel 11. For example, the fixing member 16 may be coupled to the rear surface of the adhesive film 12 (see FIG. 8) on the outside of the display panel 11.

A first fixing member 16a may extend along the right side of the display panel 11 and may be attached or fixed to the rear surface of the transparent panel 13. A first fixing portion 16ap may protrude rearward from the first fixing member 16a.

A second fixing member 16b may extend along the left side of the display panel 11 and may be attached or fixed to the rear surface of the transparent panel 13. A second fixing portion 16bp may protrude rearward from the second fixing member 16b.

A third fixing member 16c may extend along the upper side of the display panel 11 and may be attached or fixed to the rear surface of the transparent panel 13. A third fixing portion 16cp may protrude rearward from the third fixing member 16c.

A bracket 25 may be attached or fixed to the rear surface of the transparent panel 13. The bracket 25 may extend along the lower side of the transparent panel 13. The bracket 25 may have a right-angled triangular cross-section. The COF 15 may be located between the lower side of the display panel 11 and the upper end of the bracket 25. A source PCB 14a, 14b may be located on the oblique side of the bracket 25. A first fixing portion 25a may protrude rightward from the right end of the bracket 25, may contact the rear surface of the transparent panel 13, and may have a plurality of holes. A second fixing portion 25b may protrude leftward from the left end of the bracket 25, may contact the rear surface of the transparent panel 13, and may have a plurality of holes.

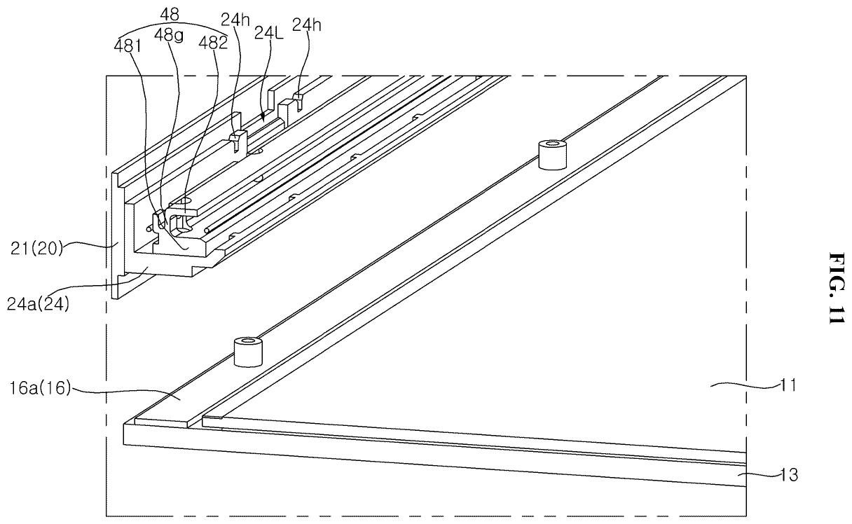

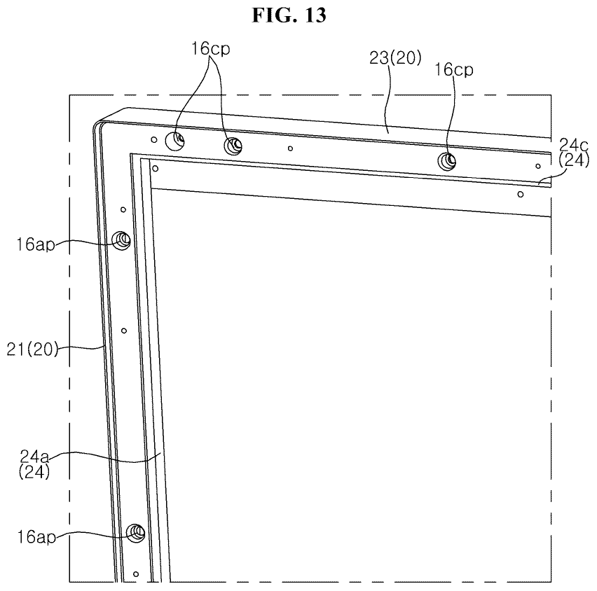

Referring to FIGS. 11 to 15 together with FIG. 10, a frame 24 may be located at the rear of a fixing member 16 and may extend along the perimeter of the transparent panel 13. The frame 24 may include a metal material.

A first frame 24a may extend along a first fixing member 16a and may be coupled to the rear surface of the first fixing member 16a. For example, a fastening member, such as a screw, may pass through the first frame 24a to be fastened to the first fixing portion 16ap of the first fixing member 16a. For example, the first fixing portion 16ap may be a pem-nut. The first frame 24a may be referred to as a right frame 24a.

A second frame 24b may extend along a second fixing member 16b and may be coupled to the rear surface of the second fixing member 16b. For example, a fastening member, such as a screw, may pass through the second frame 24b to be fastened to the second fixing portion 16bp of the second fixing member 16b. For example, the second fixing portion 16bp may be a pem-nut. The second frame 24b may be referred to as a left frame 24b.

A third frame 24c may extend along a third fixing member 16c and may be coupled to the rear surface of the third fixing member 16c. For example, a fastening member, such as a screw, may pass through the third frame 24c to be fastened to the third fixing portion 16cp of the third fixing member 16c. For example, the third fixing portion 16cp may be a pem-nut. The third frame 24c may be referred to as a top frame 24c. The third frame 24c may include an inner wall 24I. The inner wall 24I may be formed under the third frame 24c.

A fourth frame 24d may extend along the bracket 25, may cover the lower side of the bracket 25, and may be coupled to the bracket 25 and/or the transparent panel 13. The fourth frame 24d may be referred to as a bottom frame 24d.

A shield 14Ca, 14Cb may cover a source PCB 14a, 14b and may be coupled to the oblique side of the bracket 25.

The side frame 20 may extend along the frame 24 and may be coupled to the frame 24. The side frame 20 may be fixed to the outer surface of the frame 24. The side frame 20 may cover the lateral surface of the transparent panel 13. For example, the side frame 20 and the frame 24 may be formed as one body by extrusion or injection-molding.

A first side frame 21 may extend along the first frame 24a and may be coupled to the first frame 24a. The first side frame 21 may define the second short side SS2 (see FIG. 1) of the display device 1.

A second side frame 22 may extend along the second frame 24b and may be coupled to the second frame 24b. The second side frame 22 may define the first short side SS1 (see FIG. 1) of the display device 1.

A third side frame 23 may extend along the third frame 24c and may be coupled to the third frame 24c. The third side frame 23 may define the first long side LS1 (see FIG. 1) of the display device 1.

A first coupling portion 24aa may be formed on the inner surface of the first frame 24a and may be adjacent to the right end of the bracket 25. The first coupling portion 24aa may have a plurality of holes aligned with a plurality of holes of a first fixing portion 25a (see FIG. 10).

A second coupling portion 24ba may be formed on the inner surface of the second frame 24b and may be adjacent to the left end of the bracket 25. The second coupling portion 24ba may have a plurality of holes aligned with a plurality of holes of a second fixing portion 25b (see FIG. 10).

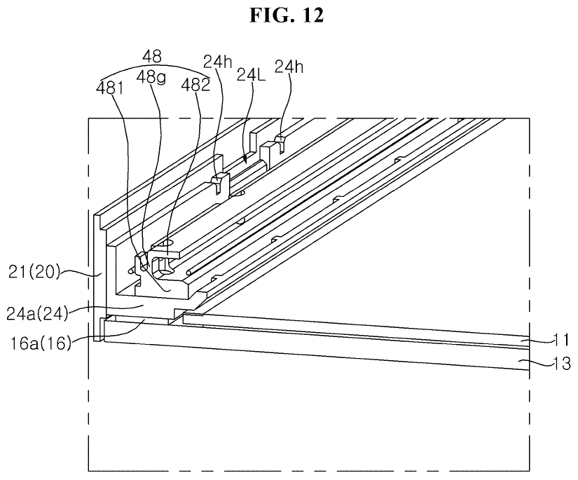

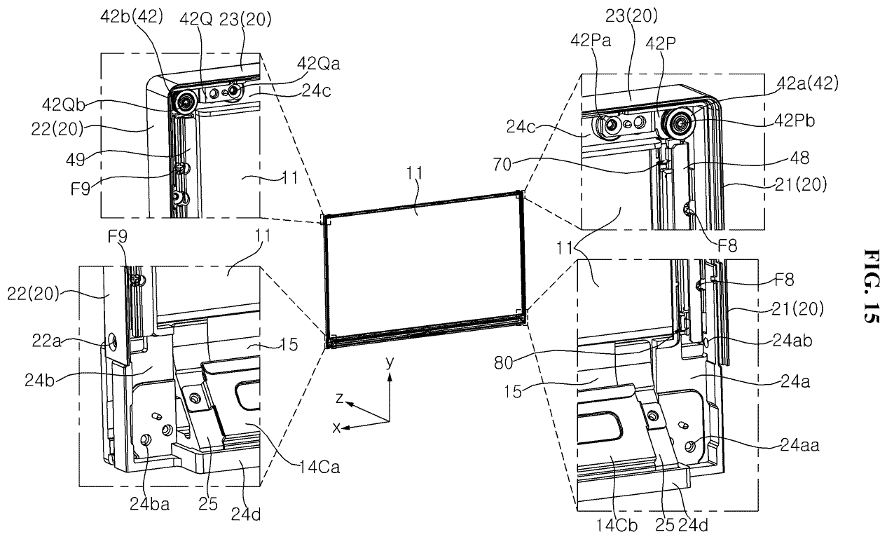

Referring to FIGS. 11 and 12 together with FIG. 15, a first guide frame 48 may be coupled to a rear surface of the first frame 24a. The first guide frame 28 may include a first front guide frame 481 and a first rear guide frame 482. The first front guide frame 481 may face the rear surface of the first frame 24a and may be fixed to the first frame 24a. The first rear guide frame 482 may be disposed at the rear of the first front guide frame 481 and may face the first front guide frame 481. A first guide groove 48g may be formed between the first front guide frame 481 and the first rear guide frame 482. The first guide groove 48g may connect the first front guide frame 481 and the first rear guide frame 482.

An alignment groove 24h may be formed in the side wall of the frame 24. The side wall of the frame 24 may face or may be parallel to the side frame 21. The side wall of the frame 24 may be supported or in contact with the side frame 21. There may be a plurality of alignment grooves 24h, and the plurality of alignment grooves 24h may be spaced apart from each other in the side wall. A latching portion 24L may be formed between a pair of alignment grooves 24h.

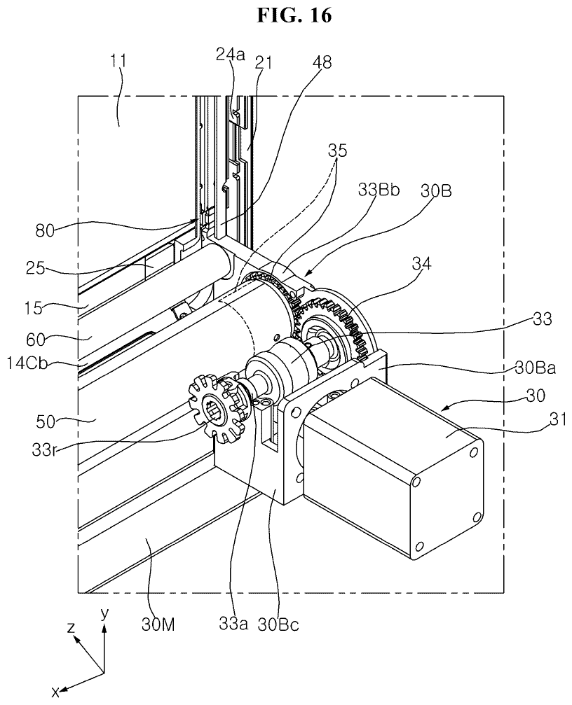

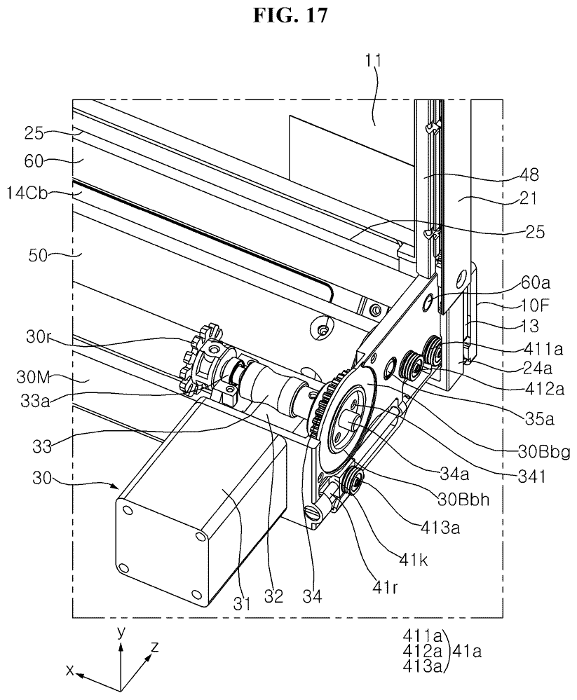

Referring to FIGS. 16 and 17, a driving assembly 30 may include a base 30M. The base 30M may be located at the rear of the bracket 25. The base 30M may be a thin plate that is elongated in the left-right direction. The base 30M may be fixed to the inside of the housing 90 (see FIG. 1).

The driving assembly 30 may include a first mount 30B. The first mount 30B may be located on the base 30M. The first mount 30B may be adjacent to the right end of the base 30M. The first mount 30B may include a first rear part 30Ba. The first rear part 30Ba may face the bracket 25 in the front-rear direction, and may be spaced rearward from the bracket 25. The first rear part 30Ba may have a square plate shape that is parallel to the XY plane. The first mount 30B may include a first side part 30Bb. The first side part 30Bb may extend forward from the right side of the first rear part 30Ba. The first side part 30Bb may be coupled to the inner surface of the first frame 24a. The first side part 30Bb may be positioned more inwardly than the first side frame 21. The first side part 30Bb may be referred to as a first side wall 30Bb. The first mount 30B may include a first support part 30Bc. The first support part 30Bc may extend forward from the left side of the first rear part 30Ba. The first support part 30Bc may face the first side part 30Bb. The first support part 30Bc may horizontally overlap at least a portion of the first side part 30Bb. A protruding length of the first support part 30Bc that protrudes forward from the left side of the first rear part 30Ba may be smaller than a protruding length of the first side part 30Bb that protrudes forward from the right side of the first rear part 30Ba. The first support part 30Bc may be horizontally spaced apart from the first side part 30Bb. The first support part 30Bc may be located on the base 30M.

The first rear prat 30Ba, the first side part 30bb, and the first support part 30Bc may be formed as one body.

The first mount 30B may be fixed to the bracket 25 and the display 10. For example, a fastening member, such as a screw, may pass through the first side part 30Bb, the first coupling portion 24aa, the first fixing portion 25a, and the transparent panel 13, and may be fastened to a front cover 10F (see FIGS. 10 and 15). The front cover 10F may be opposite the first coupling portion 24aa with respect to the transparent panel 13.

The driving assembly 30 may include a motor 31. The motor 31 may be located at the rear of the first rear part 30Ba. For example, a rotating shaft of the motor 31 may extend in the front-rear direction. The rotating shaft of the motor 31 may pass through the first rear part 30Ba. The motor 31 may provide torque. For example, the motor 31 may be an electric motor with adjustable rotation direction, rotation angle, and rotation speed control.

The driving assembly 30 may include a worm 32. The worm 32 may be disposed between the first side part 30Bb and the first support part 30Bc. A rotation axis of the worm 32 may be parallel to the rotating shaft of the motor 31. The rotation axis of the worm 32 may be coaxial with the rotating shaft of the motor 31. For example, the rotation axis of the worm 32 may extend in the front-rear direction. One end of the worm 32 may be fixed to the rotating shaft of the motor 31. The worm 32 may rotate together with the rotating shaft of the motor 31. Screw-shaped gear teeth may be formed on an outer circumferential surface of the worm 32, and the worm 32 may be referred to as a worm shaft 32.

The driving assembly 30 may include a worm wheel 33. The worm wheel 33 may be disposed between the first side part 30Bb and the first support part 30Bc. The worm wheel 33 may be located above the worm 32. The worm wheel 33 may mesh with the gear teeth of the worm 32. A rotation axis of the worm wheel 33 may be orthogonal to the rotation axis of the worm 32. For example, the rotation axis of the worm 32 may extend in the front-rear direction, and the rotation axis of the worm wheel 33 may extend in the left-right direction. The worm wheel 33 may be a helical gear.

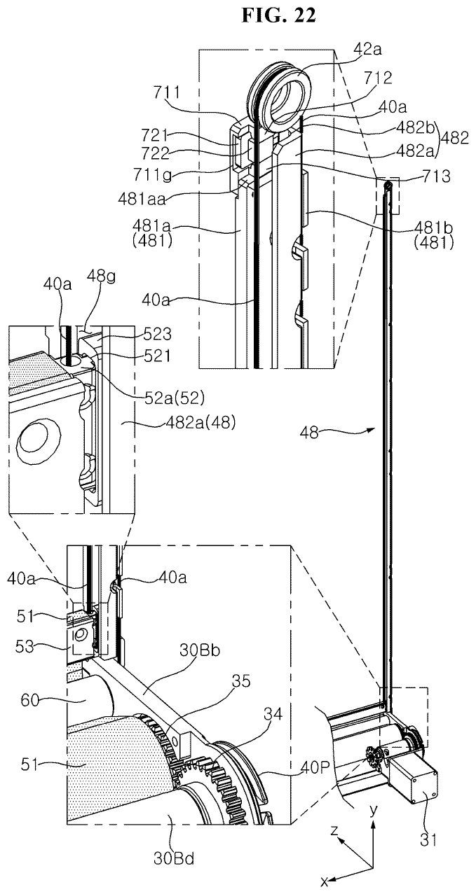

A first gear 34 which will be described below may be fixed to a first end of the worm wheel 33. A bearing 33a may be located at a second end of the worm wheel 33. The bearing 33a may support a portion adjacent to the second end of the worm wheel 33. The worm bearing 33a may be disposed between the first support part 30Bc and a gear cover 30Bd (see FIG. 22). The gear cover 30Bd may be removably coupled to the first support part 30Bc and may cover the worm 32 and the worm wheel 33.

The driving assembly 30 may include the first gear 34. The first gear 34 may be fixed to the first end of the worm wheel 33. The first gear 34 may include a shaft 34a. The shaft 34a of the first gear 34 may provide a rotation axis 34a of the first gear 34. The rotation axis 34a of the first gear 34 may be coaxial with the rotation axis of the worm wheel 33. For example, the rotation axis 34a of the first gear 34 may extend in the left-right direction. The first gear 34 may be a spur gear. The first gear 34 may be in contact with or adjacent to the inside of the first side part 30Bb. A fixing portion 341 of the first gear 34 may be disposed in a hole 30Bbh formed in the first side part 30Bb. The shaft 34a of the first gear 34 may be formed on the fixing portion 341.

The driving assembly 30 may include a second gear 35. The second gear 35 may be located in front of the first gear 34. The second gear 35 may mesh with the first gear 34. The second gear 35 may include a shaft 35a. The shaft 35a of the second gear 35 may provide a rotation axis 35a of the second gear 35. The rotation axis 35a of the second gear 35 may be parallel to the rotation axis 34a of the first gear 34. Accordingly, the second gear 35 may rotate together with the first gear 34. The second gear 35 may be a spur gear. The second gear 35 may be in contact with or adjacent to the inside of the first side part 30Bb. The shaft 35a of the second gear 35 may pass through the first side part 30Bb.

The driving assembly 30 may include a first lower pulley 41a. The first lower pulley 41a may be located on the first side part 30Bb. The first lower pulley 41a may be rotatably coupled to the first side part 30Bb. In this case, a rotation axis of the first lower pulley 41a may be parallel to the rotation axes 34a and 35a of the first and second gears 34 and 35. Alternatively, the first lower pulley 41a may be fixed to the first side part 30Bb.

The first lower pulley 41a may include a plurality of first lower pulleys 41a. The plurality of first lower pulleys 41a may be spaced apart from each other. For example, the plurality of first lower pulleys 41a may include a first guide pulley 411a and a tension pulley 412a, 413a. The first guide pulley 41a may be disposed in front of the tension pulley 412a, 413a. The tension pulley 412a, 413a may include a plurality of tension pulleys 412a, 413a. The plurality of tension pulleys 412a, 413a may be spaced apart from each other. For example, the plurality of tension pulleys 412a, 413a may include a first tension pulley 412a and a second tension pulley 413a. The first tension pulley 412a may be disposed in front of the second tension pulley 413a. The first tension pulley 412a may be disposed between the first guide pulley 411a and the second tension pulley 412a. The second tension pulley 413a may be disposed behind the second tension pulley 412a. The first guide pulley 411a, the first tension pulley 412a, and the second tension pulley 413a may be positioned at different heights.

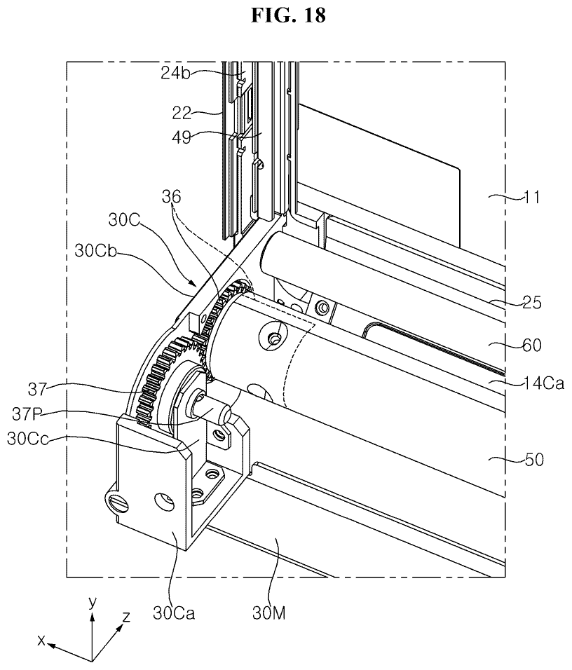

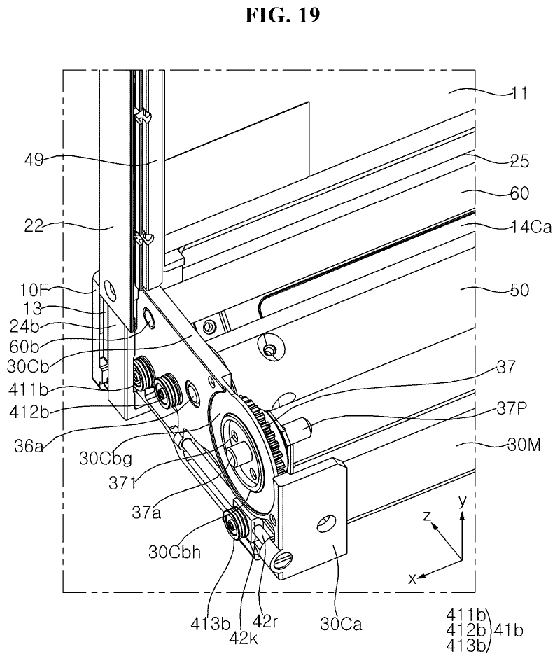

Referring to FIGS. 18 and 19, the driving assembly 30 may include a second mount 30C. The second mount 30C may be located on the base 30M. The second mount 30C may be adjacent to the left end of the base 30M. The second mount 30C may face the first mount 30B in the left-right direction. The second mount 30C may include a second rear part 30Ca. The second rear part 30Ca may face the bracket 25 in the front-rear direction and may be spaced rearward from the bracket 25. The first rear part 30Ba may have a square plate shape that is parallel to the XY plane.

The second mount 30C may include a second side part 30Cb. The second side part 30Cb may extend forward from the left side of the second rear part 30Ca. The second side part 30Cb may be coupled to the inner surface of the second frame 24b. The second side part 30Cb may be positioned more inwardly than the second side frame 22. The second side part 30Cb may be referred to as a second side wall 30Bb. The second rear part 30Ca and the second side part 30Cb may be formed as one body. The second mount 30C may include a second support part 30Cc. The second support part 30Cc may be coupled to a bottom plate (not numbered) of the second mount 30C or the base 30M. The second support part 30Cc may be positioned further to the left than the right side of the second mount 30C. The second support part 30Cc may face the second side part 30Cb. The second support part 30Cc may be spaced rightward from the second side part 30Cb.

The second mount 30C may be fixed to the bracket 25 and the display 10. For example, a fastening member, such as a screw, may pass through the second side part 30Cb, the second coupling portion 24ba, the fixing portion 25b, and the transparent panel 13, and may be fastened to the front cover 10F (see FIGS. 10 and 15).

The driving assembly 30 may include a third gear 36. The third gear 36 may face the second gear 35 in the left-right direction. The third gear 36 may include a shaft 36a. The shaft 36a of the third gear 36 may provide a rotation axis 36a of the third gear 36. The rotation axis 36a of the third gear 36 may extend in the same direction as the extending direction of the rotation axis 35a of the second gear 35. For example, the rotation axis 36a of the third gear 36 may extend in the left-right direction. The rotation axis 36a of the third gear 36 may be coaxial with the rotation axis 35a of the second gear 35. Accordingly, the third gear 36 may rotate together with the second gear 35. The third gear 36 may be a spur gear. The third gear 36 may be in contact with or adjacent to the inside of the second side part 30Cb. The shaft 36a of the third gear 36 may pass through the second side part 30Cb.

The driving assembly 30 may include a fourth gear 37. The fourth gear 37 may be located behind the third gear 36. The fourth gear 37 may mesh with the third gear 36. The fourth gear 37 may include a shaft 37a. The shaft 37a of the fourth gear 37 may provide a rotation axis 37a of the fourth gear 37. The rotation axis 37a of the fourth gear 37 may be parallel to the rotation axis 36a of the third gear 36. Accordingly, the fourth gear 37 may rotate together with the third gear 36. The fourth gear 37 may be a spur gear.

The fourth gear 37 may be disposed between the second side part 30Cb and the second support part 30Cc. The fourth gear 37 may be in contact with or adjacent to the inside of the second side part 30Cc. A fixing portion 371 of the fourth gear 37 may be disposed in a hole 30Cbh formed in the second side part 30Cb. The shaft 37a of the fourth gear 37 may be formed on the fixing portion 371. A pin 37P of the fourth gear 37 may be opposite the shaft 37a and rotatably coupled to the second support part 30Cc.

The fourth gear 37 may horizontally overlap the first gear 34. The rotation axis 37a of the fourth gear 37 may extend in the same direction as the extending direction of the rotation axis 34a of the first gear 34. For example, the rotation axis 37a of the fourth gear 37 may extend in the left-right direction. The rotation axis 37a of the fourth gear 37 may be coaxial with the rotation axis 35a of the first gear 34. Accordingly, the fourth gear 37 may rotate together with the first gear 34.

The driving assembly 30 may include a second lower pulley 41b. The second lower pulley 41b may be located on the second side part 30Cb. The second lower pulley 41b may be rotatably coupled to the second side part 30Cb. In this case, a rotation axis of the second lower pulley 41b may be parallel to the rotation axes 36a and 37a of the third and fourth gears 36 and 37. Alternatively, the second lower pulley 41b may be fixed to the second side part 30Cb.

The second lower pulley 41b may include a plurality of second lower pulleys 41b. The plurality of second lower pulleys 41b may be spaced apart from each other. For example, the plurality of second lower pulleys 41b may include a second guide pulley 411b and a tension pulley 412b, 413b. The second guide pulley 411b may be disposed in front of the tension pulley 412b, 413b. The tension pulley 412b, 413b may include a plurality of tension pulleys 412b, 413b. The plurality of tension pulleys 412b, 413b may be spaced apart from each other. For example, the plurality of tension pulleys 412b, 413b may include a third tension pulley 412b and a fourth tension pulley 413b. The third tension pulley 412b may be disposed in front of the fourth tension pulley 413b. The third tension pulley 412b may be disposed between the second guide pulley 411b and the fourth tension pulley 413b. The fourth tension pulley 413b may be disposed behind the third tension pulley 412b. The second guide pulley 411b, the third tension pulley 412b, and the fourth tension pulley 413b may be positioned at different heights.

Referring to FIGS. 16 to 19, a roller 50 may be in the shape of a hollow cylinder. The roller 50 may be disposed between the first side part 30Bb and the second side part 30Cb. A right end of the roller 50 may be positioned on the first side part 30Bb. The right end of the roller 50 may be coupled to the second gear 35. A portion of the second gear 35 (see the dotted line in FIG. 16) may be located inside the roller 50. A left end of the roller 50 may be positioned on the second side part 30Cb. The left end of the roller 50 may be coupled to the third gear 36. A portion of the third gear 36 (see the dotted line in FIG. 18) may be located inside the roller 50. The roller 50 may be elongated in the left-right direction which is a direction parallel to the rotation axes 35a, 36a of the second gear 35 and/or the third gear 36. The second gear 35 and the third gear 36 may rotate together with the roller 50.

A sub-roller 60 may be elongated in a direction parallel to the longitudinal direction of the roller 50. For example, the sub-roller 60 may be elongated in the left-right direction. The sub-roller 60 may have a cylindrical shape. The sub-roller 60 may be disposed between the roller 50 and the display panel 11. A first shaft 60a (see FIG. 17) of the sub-roller 60 may pass through the first side part 30Bb. The first shaft 60a may provide a rotation axis of the sub-roller 60. Alternatively, the sub-roller 60 may also be fixed to the first side part 30Bb. A second shaft 60b (see FIG. 19) of the sub-roller 60 may pass through the second side part 30Cb. The second shaft 60b may provide a rotation axis of the sub-roller 60. Alternatively, the sub-roller 60 may also be fixed to the second side part 30Cb. The sub-roller 60 may be referred to as an auxiliary roller 60.

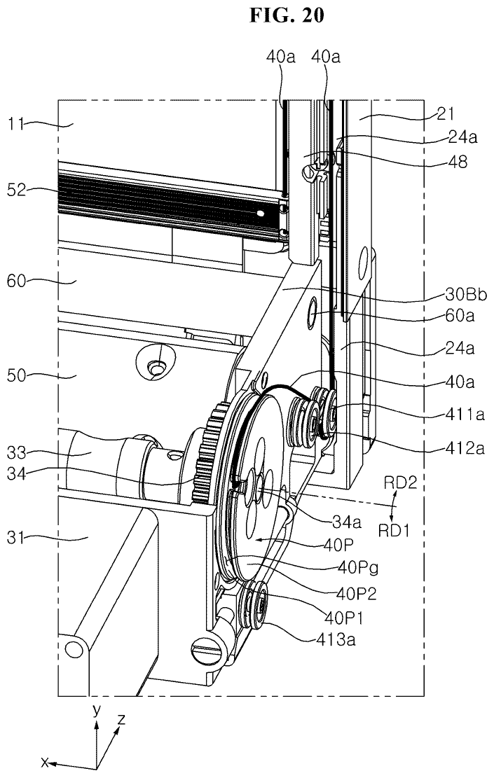

Referring to FIG. 20, a first reel 40P may be located on the first side part 30Bb. The first reel 40P may be rotatably coupled to an outer lateral surface of the first side part 30Bb. The first reel 40P may be seated in a first seating recess 30Bbg (see FIG. 17) of the first side part 30Bb and may be fixed by the fixing portion 341 (see FIG. 17). The shaft 34a of the first gear 34 may pass through a reel body of the first reel 40P. Accordingly, the first reel 40P may rotate together with the first gear 34.

The first reel 40P may have a generally flat cylindrical shape. The first reel 40P may have a first groove 40Pg. The first groove 40Pg may be formed in an outer circumferential surface of the first reel 40P. The first reel 40P may include a first circular plate 40P1. The first circular plate 40P1 may extend from a first end of the reel body of the first reel 40P in a radial direction of the reel body. The first circular plate 40P1 may define the left surface of the reel body. The first circular plate 40P1 may face or contact the first seating recess 30Bbg. The first reel 40P may include a second circular plate 40P2. The second circular plate 40P2 may extend from a second end of the reel body of the first reel 40P in a radial direction of the reel body. The second circular plate 40P2 may define the right surface of the reel body. The first groove 40Pg of the first reel 40P may be formed between the first circular plate 40P1 and the second circular plate 40P2.

A bar 52 may be located above the roller 50. The bar 52 may be spaced apart from the roller 50 in a radial direction of the roller 50. The bar 52 may extend in a direction parallel to the longitudinal direction of the roller 50. For example, the bar 52 may extend in the left-right direction. The bar 52 may have a square plate shape. For example, the bar 52 may have a solid lumver shape as a whole. The bar 52 may include a metal material or a plastic material. The bar 52 may be located behind the display panel 11. The bar 52 may be located closer to the display panel 11 than the roller 50 at the rear of the display panel 11. The bar 52 may be referred to as a pole 52.

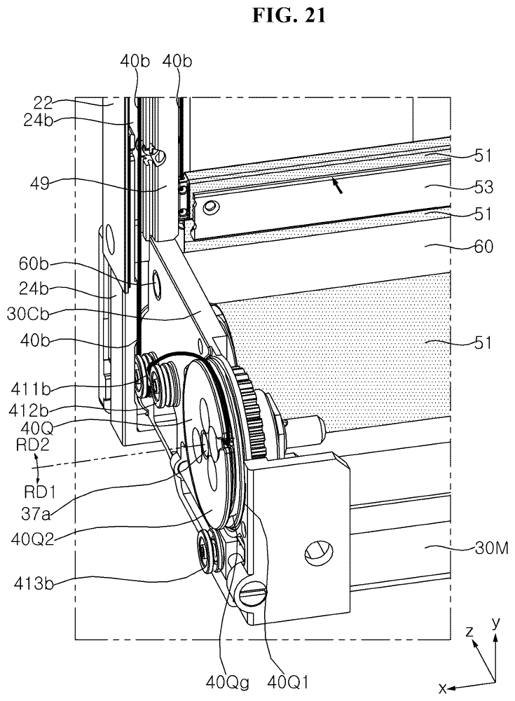

Referring to FIG. 21, a second reel 40Q may be located on the second side part 30Cb. The second reel 40Q may be rotatably coupled to an outer lateral surface of the second side part 30Cb. The second reel 40Q may be seated in a second seating recess 30Bbg (see FIG. 19) of the second side part 30Cb and may be fixed by the fixing portion 371 (see FIG. 19). The shaft 37a of the fourth gear 37 may pass through a reel body of the second reel 40Q. Accordingly, the second reel 40Q may rotate together with the fourth gear 37.

The second reel 40Q may have a generally flat cylindrical shape. The second reel 40Q may have a second groove 400g. The second groove 40Qg may be formed in an outer circumferential surface of the second reel 40Q. The second reel 40Q may include a first circular plate 40Q1. The first circular plate 40Q1 may extend from a first end of the reel body of the second reel 40Q in a radial direction of the reel body. The first circular plate 40Q1 may define the right surface of the reel body. The first circular plate 40Q1 may face or contact the second seating recess 30Cbg. The second reel 40Q may include a second circular plate 40Q2. The second circular plate 40Q2 may extend from a second end of the reel body of the second reel 40Q in a radial direction of the reel body. The second circular plate 40Q2 may define the right surface of the reel body. The second groove 40Qg of the second reel 40Q may be formed between the first circular plate 40Q1 and the second circular plate 40Q2.

A first end of the cover sheet 51 may be fixed to the roller 50, and a second end of the cover sheet 51 may be fixed to the bar 52 (see FIG. 20). A portion of the cover 51 may cover the bar 52 (see FIG. 20). The portion of the cover 51 may be sandwiched between the bar 52 and a coupler 53 (see FIG. 20). The cover sheet 51 may be attached to the bar 52 by an adhesive member, may be heat-sealed, or may be fixed by a screw and the like. The cover sheet 51 may be wound around or unwound from the roller 50 and may be hung on the sub-roller 60. The cover sheet 51 may include a fabric material. The cover 51 may take on a black color or other colors.

Referring back to FIG. 15, a first guide frame 48 may extend along the first frame 24a. The first guide frame 48 may be coupled to the rear surface of the first frame 24a. For example, a fastening member F8, such as a screw, may pass through the first guide frame 48 and may be fastened to the first frame 24a. For example, the fastening member F8, such as a screw, may pass through the first guide frame 48 and may be fastened to the first frame 24a.

A first holder 42P may be located above the first guide frame 48. The first holder 42P may extend in the longitudinal direction of the third frame 24c. A fastening member, such as a screw, may pass through a hole 42Pa of the first holder 42P and may be fastened to the third frame 24c. A first upper pulley 42a may be rotatably coupled to a pin 42Pb protruding rearward from the first holder 42P. Alternatively, the first upper pulley 42a may be fixed to the pin 42Pb protruding rearward from the first holder 42P. The first upper pulley 42a may be adjacent to the upper end of the first guide frame 49. The first upper pulley 42a may be located above the first guide frame 48. The first upper pulley 42a may overlap the first guide frame 48 in the longitudinal direction of the first guide frame 48. A rotation axis of the first upper pulley 42a may be parallel to the front-rear direction. Meanwhile, the first upper pulley 42a and the first lower pulley 41a (see FIG. 17) may be collectively referred to as a first pulley 42a, 41a.

A second guide frame 49 may extend along the second frame 24b. The second guide frame 49 may be coupled to the rear surface of the second frame 24b. For example, a fastening member F9, such as a screw, may pass through the second guide frame 49 and may be fastened to the second frame 24b. For example, the fastening member F9, such as a screw, may pass through the second guide frame 49 and may be fastened to the second frame 24b.

A second holder 42Q may be located above the second guide frame 49. The second holder 42Q may extend in the longitudinal direction of the third frame 24c. A fastening member, such as a screw, may pass through a hole 42Qa of the second holder 42Q and may be fastened to the third frame 24c. A second upper pulley 42b may be rotatably coupled to a pin 42Qb protruding rearward from the second holder 42Q. Alternatively, the second upper pulley 42b may be fixed to the pin 42Qb protruding rearward from the second holder 42Q. The second upper pulley 42b may be adjacent to the upper end of the second guide frame 49. The second upper pulley 42b may be located above the second guide frame 49. The second upper pulley 42b may vertically overlap the second guide frame 49. A rotation axis of the second upper pulley 42b may be parallel to the front-rear direction. Meanwhile, the second upper pulley 42b and the second lower pulley 41b (see FIG. 19) may be collectively referred to as a second pulley 42b, 41b.

Referring to FIGS. 20 and 22, a first end of a first wire 40a may be fixed to the reel body of the first reel 40P. A second end of the first wire 40a may be adjacent to the right end of the bar 52 and fixed to the bar 52. A portion of the fist wire 40a may be located in the first groove 40Pg of the first reel 40P and may be wound around or unwound from the reel body of the first reel 40P. Alternatively, instead of the first wire 40a, a first cable 40a, a first rope 40a, a first string 40a, a first chain 40a, a first band 40a, a first strap 40a, or a first belt 40a may be wound around or unwound from the first reel 40P. The first wire 40a, the first cable 40a, the first rope 40a, the first string 40a, the first chain 40a, the first band 40a, the first strap 40a, and the first belt 40a may be referred to as a first connection member 40a.

The first wire 40a may be caught on the outer circumference of the first guide pulley 411a. The first wire 40a may be bent by the first guide pulley 411a. The first wire 40a bent by the first guide pulley 411a may be located on the right of the first guide frame 48 and may extend in a direction parallel to the first guide frame 48. The first wire 40a may be caught on the outer circumference of the first upper pulley 42a and may be bent 180 degrees around the z-axis by the first upper pulley 42a. The first wire 40a bent by the first upper pulley 42a may be located on the left of the first guide frame 48, may extend in a direction parallel to the first guide frame 48, and may be fixed to a portion 52a adjacent to the right end of the bar 52.

A first protrusion 521 may define the right end of the bar 52 and may be vertically movably inserted into a first guide groove 48g of the first guide frame 48. The first guide groove 48g may be formed in the left surface of the first guide frame 48 and may extend vertically.

The first guide frame 48 may be coupled to the rear surface of the first frame 24a. The first guide frame 48 may include a first front guide frame 481 and a first rear guide frame 482. The first front guide frame 481 may face the rear surface of the first frame 24a. The first rear guide frame 482 may be disposed at the rear of the first front guide frame 481 and may face the first front guide frame 481. A first guide groove 48g may be formed between the first front guide frame 481 and the first rear guide frame 482. The first front guide frame 481 may include a first horizontal portion 481a. The first horizontal portion 481a may be parallel to the first frame 24a. For example, the first horizontal portion 481a may have a plate shape that extends vertically. The first front guide frame 481 may include a first vertical portion 481b. The first vertical portion 481b may face the first side frame 21. The first horizontal portion 481a and the first vertical portion 481b may be formed as one body.

The first rear guide frame 482 may include a second horizontal portion 482a. The second horizontal portion 482a may face the first horizontal portion 481a. The second horizontal portion 482a may be parallel to the first horizontal portion 481a. For example, the second horizontal portion 482a may have a plate shape that extends vertically. The second horizontal portion 482a may be spaced rearward from the first horizontal portion 481a. The first guide groove 48g may be formed between the first horizontal portion 481a and the second horizontal portion 482a. The first rear guide frame 482 may include a second vertical portion 482b. The second vertical portion 482b may extend forward from one side of the second horizontal portion 481a. The second vertical portion 482b may face the first vertical portion 481b. The second vertical portion 482b may be positioned inside the first vertical portion 481b. The second horizontal portion 482a and the second vertical portion 482b may be formed as one body.

An upper end 481aa of the first front guide frame 481 may be located below an upper end of the first rear guide frame 482. A first sensor 70 may be seated at the upper end 481aa of the first front guide frame 481. A second grip portion 713 of the first sensor 70, which will be described later, may be supported by the upper end 481aa of the first front guide frame 481.

A lower end of the first front guide frame 481 may be located above a lower end of the first rear guide frame 482. That is, a vertical length of the first front guide frame 481 may be smaller than a vertical length of the first rear guide frame 482. A second sensor 80 may be seated at the lower end of the first front guide frame 481. A fourth grip portion 814 of the second sensor 80, which will be described later, may be supported by the lower end of the first front guide frame 481.

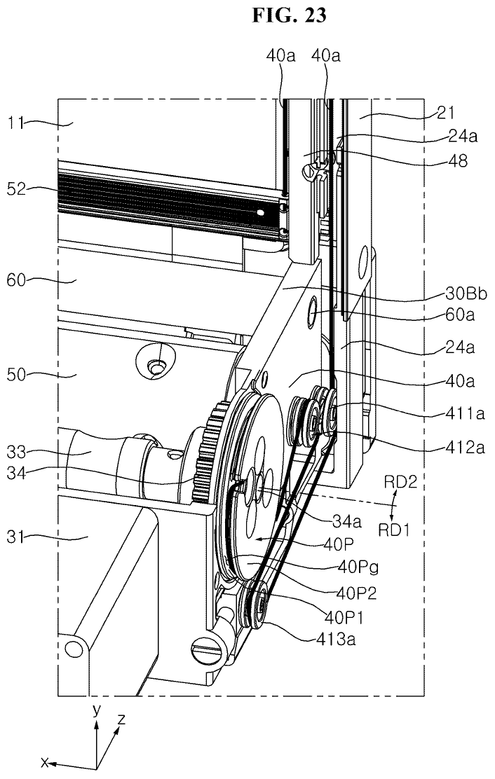

Referring to FIGS. 20 and 23, the first wire 40a from the first reel 40P may be hung on any one pulley of the first tension pulley 412a or the second tension pulley 413a, and thus may be bent. For example, the first wire 40a may be hung on the outer circumference of the first tension pulley 412a and bent, and then may be hung on the outer circumference of the first guide pulley 411a. For example, the first wire 40a may be hung on the outer circumference of the second tension pulley 413a and bent, and then may be hung on the outer circumference of the first guide pulley 411a. For example, the first wire 40a may be hung on both the first and second tension pulleys 412a and 413a and bent, and then may be hung on the outer circumference of the first guide pulley 411a. In this case, the first wire 40a may be first hung on the first tension pulley 412a and bent, and then may be hung on the second tension pulley 413a and bent, and may be hung on the outer circumference of the first guide pulley 411a. In this case, the first wire 40a may be bent in a zigzag shape. In this manner, the tension of the first wire 40a may be controlled.

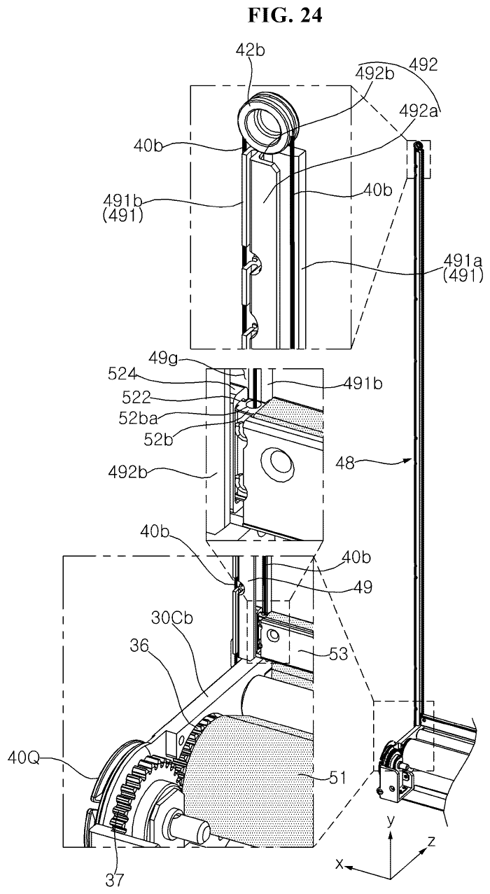

Referring to FIGS. 21 and 24, a first end (not numbered) of the second wire 40b may be fixed to the reel body of the second reel 40Q. A second end (not numbered) of the second wire 40b may be adjacent to the left end of the bar 52 and fixed to the bar 52. A portion of the second wire 40b may be located in the second groove 40Qg of the second reel 40Q, and may be wound around or unwound from the reel body of the second reel 40Q. Alternatively, instead of the second wire 40b, a second cable 40b, a second rope 40b, a second string 40b, a second chain 40b, a second band 40b, a second strap 40b, or a second belt 40b may be wound around or unwound from the second reel 40Q. The second wire 40b, the second cable 40b, the second rope 40b, the second string 40b, the second chain 40b, the second band 40b, the second strap 40b, and the second belt 40b may be referred to as a second connection member 40b.

The second wire 40b may be hung on the outer circumference of the second guide pulley 411b. The second wire 40b may be bent by the second guide pulley 411b. The second wire 40b bent by the second guide pulley 411b may be located on the left of the second guide frame 49 and may extend in a direction parallel to the second guide frame 49. The second wire 40b may be hung on the outer circumference of the second upper pulley 42b and may be bent 180 degrees around the z-axis by the second upper pulley 42b. The second wire 40b bent by the second upper pulley 42b may be located on the right of the second guide frame 49, may extend in a direction parallel to the second guide frame 49, and may be fixed to a portion 52b adjacent to the left end of the bar 52.

A second protrusion 522 may define the left end of the bar 52 and may be vertically movably inserted into a second guide groove 49g of the second guide frame 49. The second guide groove 49g may be formed in the right surface of the second guide frame 48 and may extend vertically.

The second guide frame 49 may be coupled to the rear surface of the second frame 24b. The second guide frame 49 may include a second front guide frame 491 and a second rear guide frame 492. The second front guide frame 491 may face the rear surface of the second frame 24b. The second rear guide frame 492 may be located at the rear of the second front guide frame 491 and may face the second front guide frame 491. A second guide groove 49g may be formed between the second front guide frame 491 and the second rear guide frame 492. The second front guide frame 491 may include a third horizontal portion 491a. The third horizontal portion 491a may be parallel to second frame 24b. For example, the third horizontal portion 491a may have a plate shape that extends vertically. The second front guide frame 491 may include a third vertical portion 491b. The third vertical portion 491b may extend rearward from one side of the third horizontal portion 491a. The third vertical portion 491b may face the second side frame 22. The third horizontal portion 491a and the third vertical portion 491b may be formed as one body.

The second rear guide frame 492 may include a fourth horizontal portion 492a. The fourth horizontal portion 492a may face the third horizontal portion 491a. The fourth horizontal portion 492a may be parallel to the third horizontal portion 491a. For example, the fourth horizontal portion 492a may have a plate shape that extends vertically. The fourth horizontal portion 492a may be spaced rearward from the third horizontal portion 491a. The second guide groove 49g may be formed between the third horizontal portion 491a and the fourth horizontal portion 492a. The second rear guide frame 492 may include a fourth vertical portion 492b. The fourth vertical portion 492b may extend forward from one side of the fourth horizontal portion 491a. The fourth vertical portion 492b may face the third vertical portion 491b. The fourth vertical portion 492b may be positioned inside the third vertical portion 491b. The fourth horizontal portion 492a and the fourth vertical portion 492b may be formed as one body.

An upper end of the second front guide frame 491 may form the same plane as an upper end of the second rear guide frame 492. A lower end of the second front guide frame 491 may form the same plane as a lower end of the second rear guide frame 492. That is, a vertical length of the second front guide frame 491 may be equal to a vertical length of the second rear guide frame 492.

The second wire 40b may be fixed to a left end 52b of the bar 52. A hole 52ba, into which the second wire 40b is inserted and fixed, may be formed at the left end 52b of the bar 52. The hole 52ba may be formed through the upper and lower surfaces of the left end 52b.

A second guide protrusion 522 may protrude leftward from the left end 52b. A second cap 524 may be mounted on the second guide protrusion 522. The second cap 524 may cover the second guide protrusion 522. The second guide protrusion 522 may be made of a metal material, and the second cap 524 may be made of a plastic material. The second cap 524 may be made of a plastic material having conductivity. For example, the second cap 524 may be made of Polyoxymethylene (POM) material.

The second guide protrusion 522, on which the second cap 524 is placed, may be located in the second guide groove 49g of the second guide frame 49, and may move within the second guide groove 49g by the movement of the bar 52. The second cap 524 may minimize a frictional force between the second guide frame 49 made of a metal material and the bar 52 made of a metal material.

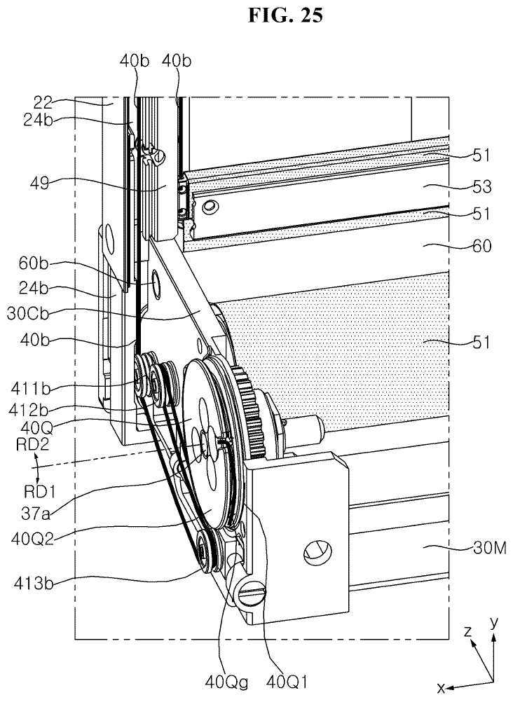

Referring to FIGS. 21 and 25, the second wire 40b from the second reel 40Q may be hung on any one pulley of the third tension pulley 412b or the fourth tension pulley 413b, and thus may be bent. For example, the second wire 40b may be hung on the outer circumference of the third tension pulley 412b and bent, and then may be hung on the outer circumference of the second guide pulley 411b. For example, the second wire 40b may be hung on the outer circumference of the fourth tension pulley 413b and bent, and then may be hung on the outer circumference of the second guide pulley 411b. For example, the second wire 40b may be hung on both the third and fourth tension pulleys 412b and 413b and bent, and then may be hung on the outer circumference of the second guide pulley 411b. In this case, the second wire 40b may be first hung on the third tension pulley 412b and bent, and then may be hung on the fourth tension pulley 413b and bent, and may be hung on the outer circumference of the second guide pulley 411b. In this case, the second wire 40b may be bent in a zigzag shape. In this manner, the tension of the first wire 40a may be controlled.

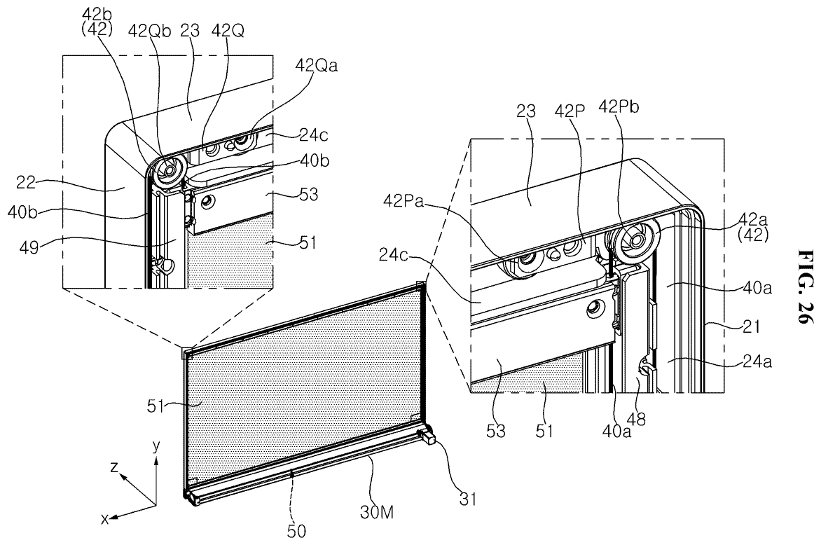

Referring to FIG. 26, the coupler 53 may be raised while moving toward the third frame 24c, or may be lowered while moving away from the third frame 24c. The motor 31 may rotate the first gear 34 in a first rotation direction RD1 or in a second direction RD2 opposite to the first rotation direction RD1 (see FIG. 20). The motor 31 may rotate the fourth gear 37 in the first rotation direction RD1 or in the second direction RD2 opposite to the first rotation direction RD1 (see FIG. 21). In this case, the first gear 34 and the fourth gear 37 may be rotated in the same direction by the motor 31. The first gear 34 and the fourth gear 37 may be rotated simultaneously by the motor 31.

When the first gear 34 and the fourth gear 37 are rotated in the first rotation direction RD1 in response to operation of the motor 31, the first reel 40P and the second reel 40Q may rotate in the first rotation direction RD1. In addition, when the first gear 34 and the fourth gear 37 are rotated in the first rotation direction RD1 in response to operation of the motor 31, the second gear 35 and the third gear 36 may be rotated in the second rotation direction RD2. In this case, the roller 50 may be rotated in the second rotation direction RD2 by the second and third gears 35 and 36. In addition, each of the first wire 40a and the second wire 40b may be wound around the first groove 40Pg and the second groove 400g, respectively, and the first wire 40a and the second wire 40b may pull the bar 52 upward. In response to raising of the bar 53 and rotation of the roller 50, the cover sheet 51 may be unwound from the roller 50 and may gradually cover the rear of the display panel 11. This motion of the driving assembly 30 may be referred to as an unfolding motion or a light blocking motion.

When the first gear 34 and the fourth gear 37 are rotated in the second rotation direction RD2 in response to operation of the motor 31, the first reel 40P and the second reel 40Q may rotate in the second rotation direction RD2. In addition, when the first gear 34 and the fourth gear 37 are rotated in the second rotation direction RD2 in response to operation of the motor 31, the second gear 35 and the third gear 36 may be rotated in the first rotation direction RD1. In this case, the roller 50 may be rotated in the first rotation direction RD1. In addition, each of the first wire 40a and the second wire 40b may be unwound from the first groove 40Pg and the second groove 400g, respectively, and the bar 52 may be lowered in a downward direction. In response to lowering of the bar 53 and rotation of the roller 50, the cover sheet 51 may be wound around the roller 50 and may gradually open the rear of the display panel 11. This motion of the driving assembly 30 may be referred to as a rolling motion or an opening motion.

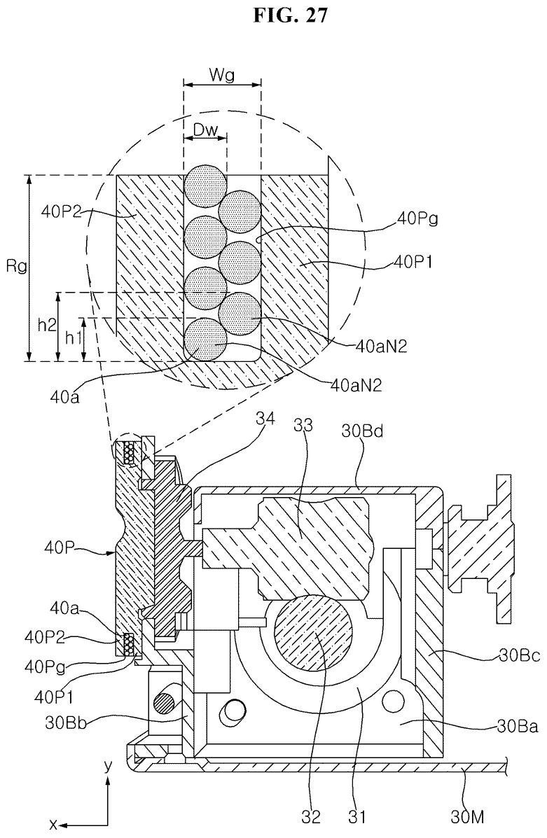

Referring to FIG. 27, the cover sheet 51, unwound from the roller 50 in response to the light blocking motion described above, may cover the rear of the display 10. In this case, the wires 40a and 40b may be wound a plurality of times around the grooves 40Pg and 400g. FIG. 27 is a diagram illustrating a cross-section of the driving assembly 30 when the first wire 40a is wound a plurality of times around the first groove 40Pg by the light blocking motion.

The first reel 40P may have the first groove 40Pg formed between the first circular plate 40P1 and the second circular plate 40P2. The first groove 40Pg may have a vertical depth Rg. The depth Rg of the first groove 40Pg may be deep enough to allow the first wire 40a to be wound a plurality of times. For example, the first wire 40a having a predetermined diameter Dw may be wound up to 7 times. For example, the diameter Dw of the first wire 40g may be 0.6 mm.

A width Wg of the first groove 40Pg may be greater than the diameter Dw of the first wire 40g, but smaller than twice the diameter Dw. In this case, the first wire 40a may be arranged in a zigzag pattern and wound a plurality of times around the first groove 40PG. For example, a height h1 of a first wire 40aN1 which is wound first around the first groove 40Pg may have a value equal to the diameter Dw of the first wire 40a, but a height h2 of a first wire 40aN2 which is wound second may have a value smaller than twice the dimeter Dw of the first wire 40a. The width Wg of the first groove 40Pg is greater than the diameter Dw of the first wire 40g, but smaller than twice the diameter Dw, thereby preventing the wound first wire 40g from moving within the first groove 40Pg.

The above description of the first wire 40a and the first groove 40Pg may also be applied to the second wire 40b and the second groove 400g. That is, the diameter Dw of the first wire 40a may be substantially equal to the diameter of the second wire 40b, and the width Wg and depth Rg of the first groove 40Pg may be substantially equal to the width and depth of the second groove 40Qg. The second wire 40b may be arranged in a zigzag pattern and may be wound around the second groove 400g a plurality of time.

Accordingly, a degree of winding of the second wire 40b around the second groove 400g may be synchronized with a degree of winding of the first wire 40a around the first groove 40Pg, and as a result, a height difference between the left upper end and the right upper end of the cover sheet 51 may be minimized.

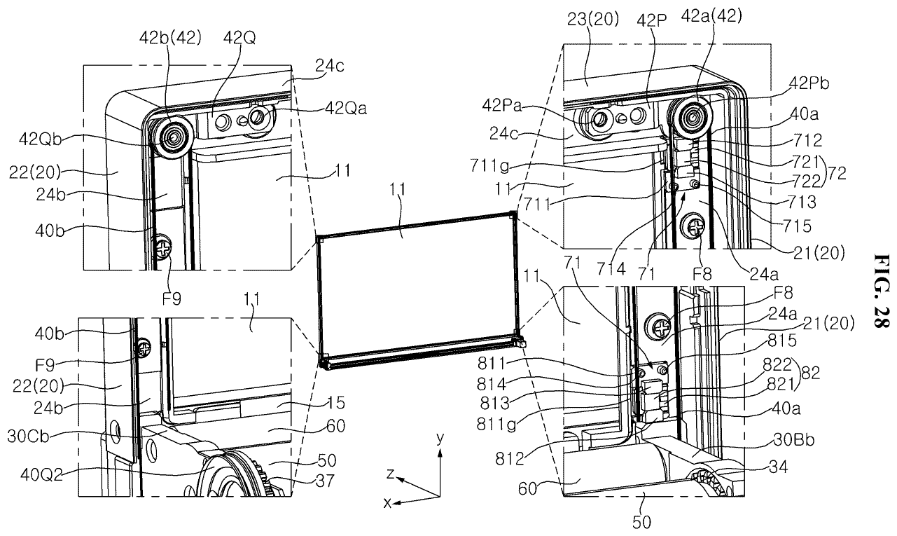

Referring to FIGS. 28 and 15, the sensor 70, 80 may be located adjacent to any one of the first side frame 21 or the second side frame 22. The sensor 70, 80 may be located adjacent to any one of the first guide frame 48 or the second guide frame 49. For example, the sensor 70, 80 may be mounted on the side of the first side frame 21 on which the motor 31 is installed.

The first sensor 70 may be coupled to the rear surface of the first frame 24a. For example, the first sensor 70 may be coupled to the first frame 24a by a fastening member such as a screw. The first sensor 70 may be adjacent to the third side frame 23. The first sensor 70 may be disposed between the first upper pulley 42a and the first guide frame 48. The first sensor 70 may be positioned in the first guide groove 48g of the first guide frame 48. The first sensor 70 may sense a top dead center of the bar 52 by sensing the first guide protrusion 521. In this manner, the movement of the bar 52 may be controlled.

The first sensor 70 may include a first sensor bracket 71. The first sensor bracket 71 may include a first base 711. The first base 711 may have a rectangular plate shape. A front surface of the first base 711 may be coupled to the rear surface of the first frame 24a. The first sensor bracket 71 may include a first receiving groove 711g recessed forward from the rear surface of the first base 711. The first receiving groove 711g may have a shape that is open at all of the rear, left, and right sides. A first sensing part 72 which will be described later may be seated in the first receiving groove 711g. The first sensor bracket 71 may include a first grip portion 712 and a second grip portion 713. The first grip portion 712 and the second grip portion 713 may be vertically spaced apart from each other. The first grip portion 712 and the second grip portion 713 may vertically face each other. The first grip portion 712 may be located above the second grip portion 713. The first grip portion 712 may be coupled to the rear surface of the first base 711 and may partially overlap the first receiving groove 711g. The second grip portion 713 may be coupled to the rear surface of the first base 711 and may partially overlap the first receiving groove 711g. The first grip portion 712 and the second grip portion 713 may overlap the first sensing part 72 in the front-rear direction. The second grip portion 713 may contact the upper end 481aa of the first horizontal portion 481a (see FIG. 22). The first sensor bracket 71 may include a protrusion 714, 715. The protrusion 714, 715 may include a plurality of protrusions 714, 715. For example, the protrusion 714, 715 may include a first protrusion 714 and a second protrusion 715. The first protrusion 714 and the second protrusion 715 may be located below the second grip portion 713. The first protrusion 714 and the second protrusion 715 may overlap horizontally. The first protrusion 714 and the second protrusion 715 may be inserted into a groove (not shown) formed in the front surface of the first horizontal portion 481a (see FIG. 22), and may support the upper end 184aa (see FIG. 22) of the first horizontal portion 481a (see FIG. 22). That is, the upper end 184aa (see FIG. 22) of the first horizontal portion 481a (see FIG. 22) may be supported on the first protrusion 714 and the second protrusion 715.

The first sensor 70 may include a first sensing part 72. The first sensing part 72 may include a first substrate 721. For example, the first substrate 721 may be a Printed Circuit Board (PCB). The first substrate 721 may be located in the first receiving groove 711g. A portion of the first substrate 721 may be inserted between the first receiving groove 711g and the first grip portion 712. A portion of the first substrate 721 may be inserted between the first receiving groove 711g and the second grip portion 713. In this manner, it is possible to prevent the first substrate 721 from separating rearwardly. The first sensing part 72 may include a first sensing chip 722. The first sensing chip 722 may be mounted on the first substrate 721. The first sensing chip 722 may protrude rearward from the first substrate 721. The first sensing chip 722 may be disposed between the first and second grip portions 712 and 713. The first sensing chip 722 may sense the first protrusion 521 of the bar 52. For example, the first sensor 70 may be a proximity sensor. For example, the first sensor 70 may be a displacement sensor.

The second sensor 80 may be coupled to the rear surface of the first frame 24a. For example, the second sensor 80 may be coupled to the first frame 24a by a fastening member such as a screw. The second sensor 80 may be adjacent to the bottom frame 24d. The second sensor 80 may be seated on the first side part 30Bb. The second sensor 80 may overlap the first sensor 70 in the longitudinal direction of the bar 52. For example, the second sensor 80 may vertically overlap the first sensor 70. The second sensor 80 may be spaced apart from the first sensor 70. The second sensor 80 may be located in the first guide groove 48g of the first guide frame 48. The second sensor 80 may sense the first guide protrusion 521. The second sensor 80 may sense a bottom dead center of the bar 52 by sensing the first guide protrusion 521. In this manner, the movement of the bar 52 may be controlled.

The second sensor 80 may include a second sensor bracket 81. The second sensor bracket 81 may include a second base 811. The second base 811 may have a rectangular plate shape. A front surface of the second base 811 may be coupled to the rear surface of the first frame 24a. The second sensor bracket 81 may include a second receiving groove 811g recessed forward from the rear surface of the second base 811. The second receiving groove 811g may have a shape that is open at all of the rear, left, and right sides. A second sensing part 82 which will be described later may be seated in the second receiving groove 811g. The second sensor bracket 81 may include a third grip portion 812 and a fourth grip portion 813. The third grip portion 812 and the fourth grip portion 813 may be vertically spaced apart from each other. The third grip portion 812 and the fourth grip portion 813 may vertically face each other. The third grip portion 812 may be located below the fourth grip portion 813. The fourth grip portion 813 may be located closer to a protrusion 814, 815, which will be described later, than the third grip portion 812. The third grip portion 812 may be coupled to the rear surface of the second base 811 and may partially overlap the second receiving groove 811g. The fourth grip portion 813 may be coupled to the rear surface of the second base 811 and may partially overlap the second receiving groove 811g. The third grip portion 812 and the second grip portion 712 may overlap the second sensing part 82 in the front-rear direction. The third grip portion 813 may contact the first side part 30Bb. The second sensor bracket 81 may include a protrusion 814, 815. The protrusion 814, 815 may include a plurality of protrusions 814, 815. For example, the protrusion 814, 815 may include a third protrusion 814 and a fourth protrusion 815. The third protrusion 814 and the fourth protrusion 815 may be located below the third grip portion 812. The third protrusion 814 and the fourth protrusion 815 may overlap horizontally. The third protrusion 814 and the fourth protrusion 815 may be inserted into a groove (not shown) formed in the front surface of the first horizontal portion 481a (see FIG. 22), and may support the lower end of the first horizontal portion 481a (see FIG. 22). That is, the lower end of the first horizontal portion 481a (see FIG. 22) may be supported on the third protrusion 814 and the fourth protrusion 815.

The second sensor 70 may include a second sensing part 82. The second sensing part 82 may include a second substrate 821. For example, the second substrate 821 may be a Printed Circuit Board (PCB). The second substrate 821 may be located in the second receiving groove 811g. A portion of the second substrate 821 may be inserted between the second receiving groove 811g and the third grip portion 812. A portion of the second substrate 821 may be inserted between the second receiving groove 811g and the fourth grip portion 813. In this manner, it is possible to prevent the second substrate 821 from separating rearwardly. The second sensing part 82 may include a second sensing chip 822. The second sensing chip 822 may be mounted on the second substrate 821. The second sensing chip 822 may protrude rearward from the second substrate 821. The second sensing chip 822 may be disposed between the third and fourth grip portions 812 and 813. The second sensing chip 822 may sense the first protrusion 521 of the bar 52. For example, the second sensor 80 may be a proximity sensor. For example, the second sensor 80 may be a displacement sensor.

An upper portion of the second vertical portion 482b (see FIG. 22) may be located on the right of the grip portion 712, 713 of the first sensor 70 and may face the first base 711 and the first substrate 721. A lower portion of the second vertical portion 482b (see FIG. 22) may be located on the right of the grip portion 812, 813 of the second sensor 80 and may face the second base 811 and the second substrate 821.

The structure of the sensor 70, 80 may allow the sensor 70, 80 to be installed in a narrow space. For example, the sensor 70, 80 may be installed within a thin bezel that supports the display panel 11. Accordingly, the sensor 70, 80 may accurately perform sensing.

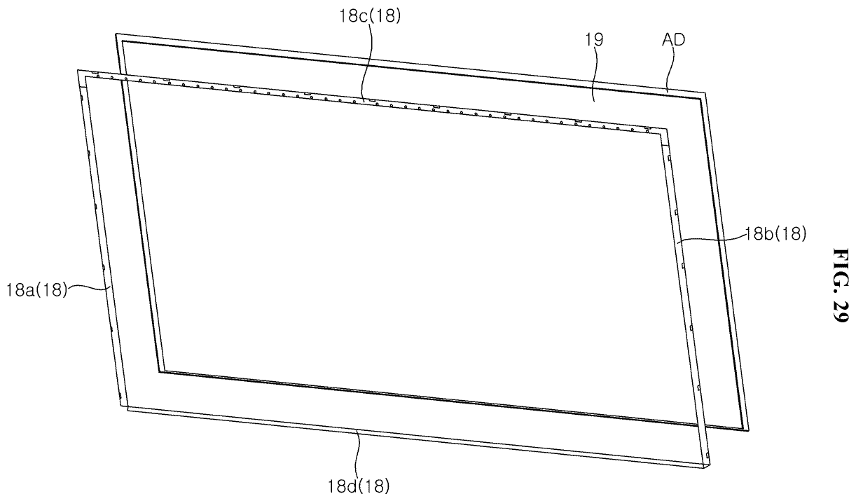

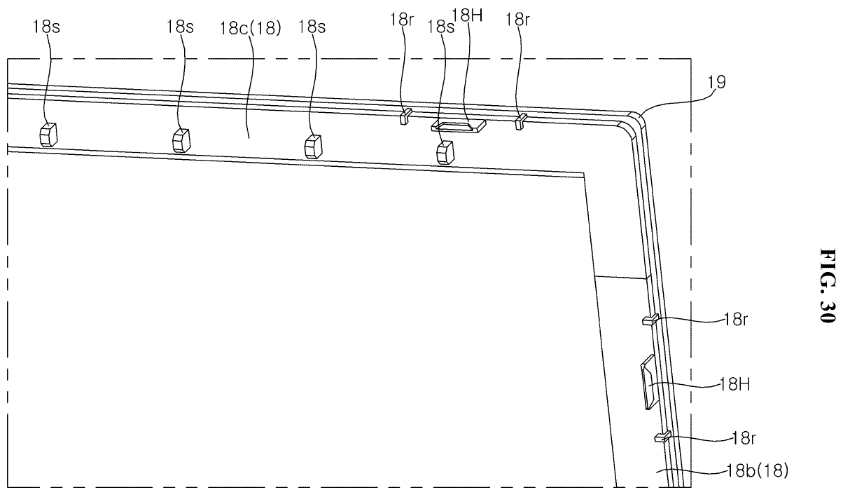

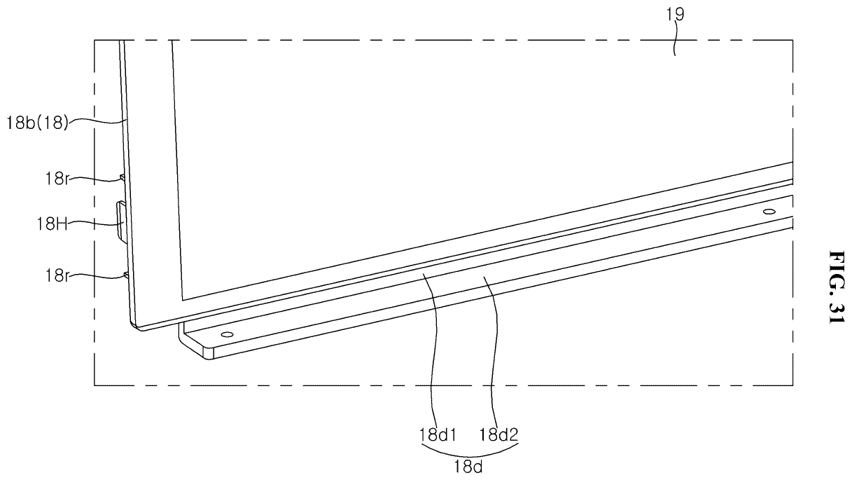

Referring to FIGS. 29 to 31, a cover frame 18a, 18b, 18c, and 18d may extend along the perimeter of the display panel 11. For example, the cover frame 18a, 18b, and 18c may include a first cover frame 18a, a second cover frame 18b, a third cover frame 18c, and a bottom frame 18d. The bottom frame 18d may include a front part 18dl and a bottom part 18d2 that are orthogonal to each other. The first cover frame 18a, the second cover frame 18b, and/or the third cover frame 18c may be formed as one body, or each may be separated from or coupled to each other.

A back cover 19 may have a size corresponding to the transparent panel 13. The back cover 19 may be made of transparent glass. The cover frame 18a, 18b, and 18c may be coupled to the front surface of the upper side and/or the front surface of the left and right sides of the back cover 19. The bottom frame 18d may be coupled to the rear surface of the lower end of the back cover 19. The front part 18dl may be attached to the rear surface adjacent to the lower end of the back cover 18, and the bottom part 18d2 may be coupled to the housing 90 (see FIG. 1).

The cover frame 18a, 18b, and 18c and/or the bottom frame 18d may be coupled to the back cover 18 by the adhesive member AD. For example, the adhesive member AD may be double-sided tape. In another example, the adhesive member AD may be bonding.

A hook 18H may be formed on the front surface of the cover frame 18a, 18b, 18c. The hook 18H may be opposite the back cover 19 with respect to the cover frame 18a, 18b, 18c. The hook 18H may protrude forward from the front surface of the cover frame 18a, 18b, 18c. There may be a plurality of hooks 18H, and the plurality of hooks 18H may be spaced apart from each other. An alignment rib 18r may be adjacent to the hook 18H and formed on the cover frame 18a, 18b, 18c. There may be a plurality of alignment ribs 18r. The hook 18H may be disposed between a pair of alignment ribs 18r. The pair of alignment ribs 18r may be spaced apart from the hook 18H.

A support rib 18s may protrude from the front surface of the cover frame 18a, 18b, 18c. There may be a plurality of support ribs 18s, and the plurality of support ribs 18s may be arranged on the front surface of the cover frame 18a, 18b, 18c while maintaining a constant distance therebetween. The support rib 18s may be located close to an inner edge of the cover frame 18a, 18b, 18c, and the hook 18H and/or the alignment ribs 18r may be located close to an outer edge of the cover frame 18a, 18b, 18c. For example, the support ribs 18s may be formed on the third cover frame 18c.

Referring together to FIG. 12, when the back cover 19 and/or the cover frame 18a, 18b, 18c are coupled to the frame 24, the alignment rib 18r may be inserted into the alignment groove 24h. A pair of alignment ribs 18r may be inserted into a pair of alignment grooves 24h. The hook 18H may be inserted into or fastened to the latching portion 24L. Accordingly, alignment may be performed for coupling between the hook 18H and the latching portion 24L.

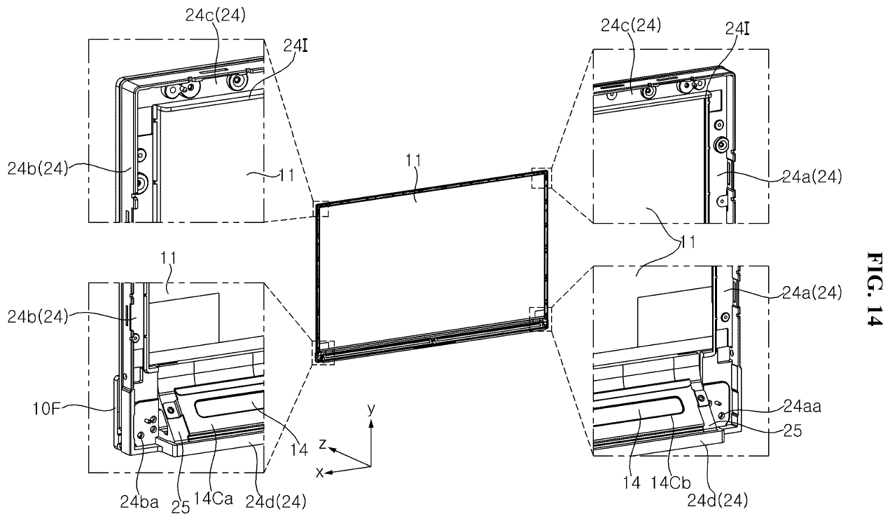

Referring together to FIG. 14, when the back cover 19 and/or the cover frame 18a, 18b, 18c are coupled to the frame 24, the support ribs 18s may be placed on the inner wall 24I of the third frame 24c. The support ribs 18s may be supported by the inner wall 24I of the third frame 24c. Accordingly, it is possible to prevent the back cover 19 and/or the cover frame 18 from sagging.

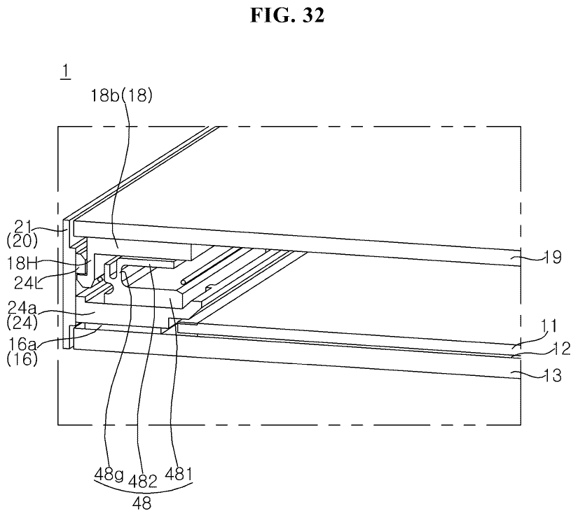

Referring to FIG. 32, the display panel 11 may be fixed to the rear surface of the transparent panel 13 by the adhesive film 12. The fixing member 16 may be elongated along the lateral surface of the display panel 11 and may be fixed to the rear surface of the transparent panel 13. The frame 24 may be coupled or fixed to the fixing member 16. The frame 24 may be opposite the transparent panel 13 with respect to the fixing member 16. The guide frame 48 may be coupled or fixed to the frame 24. The front guide frame 481 of the guide frame 48 may be in contact with the frame 24 and fixed to the frame 24.

The cover frame 18 may be located on the guide frame 48. The cover frame 18 may be coupled or fixed to the frame 24 by the hook 18H and the latching portion 24L. The cover frame 18 may be supported by or in contact with the rear guide frame 482 of the guide frame 48. The back cover 19 may be fixed or coupled to the cover frame 18. The side frame 20 may cover the lateral surface of the back cover 19, the frame 24, the cover frame 18, the fixing member 16, and/or the transparent panel 13. The side frame 20 may be coupled or fixed to the frame 24.

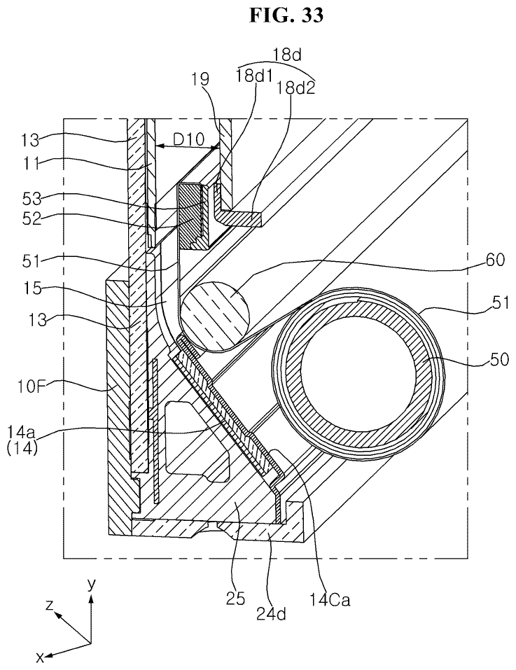

Referring to FIG. 33, the bar 52 and the coupler 53 may be raised or lowered in a space (see D10 of FIG. 36) between the display panel 11 and the back cover 19. The cover sheet 51 may be hung on the auxiliary roller 60, and may be located between the bar 52 and the auxiliary roller 60 and parallel to the display panel 11.

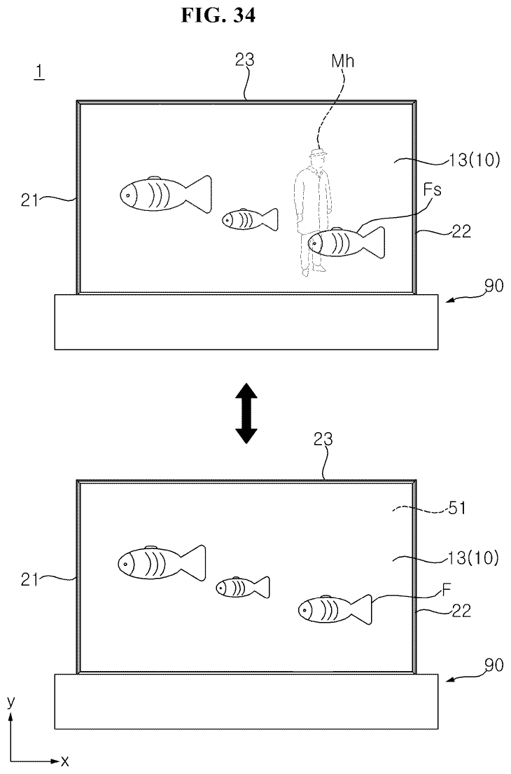

Referring to the upper view of FIG. 34, the cover sheet 51 may not cover the rear of the display 10. For example, the display 10 may not output an image, and a user in front of the display 10 may see behind the display 10 (see a man Mh wearing a hat indicated by the dotted line). In another example, the display 10 may output an image, and a user in front of the display 10 may see the image (see fish Fs indicated by the solid line) and see behind the display 10 (see a man Mh wearing a hat indicated by the dotted line). This mode may be referred to as a light transmitting mode.

Referring to the lower view of FIG. 34, the cover sheet 51 may cover the rear of the display 10. The display 10 may or may not output an image, and a user in front of the display 10 may not see behind the display 10. This mode may be referred to as a light blocking mode.

The visibility of an image output by the display 10 in the light blocking mode may be better than the visibility of an image output by the display 10 in the light transmitting mode (see comparison between the fish Fs indicated by the thin line and the fish F indicated by the thick line in FIG. 34).

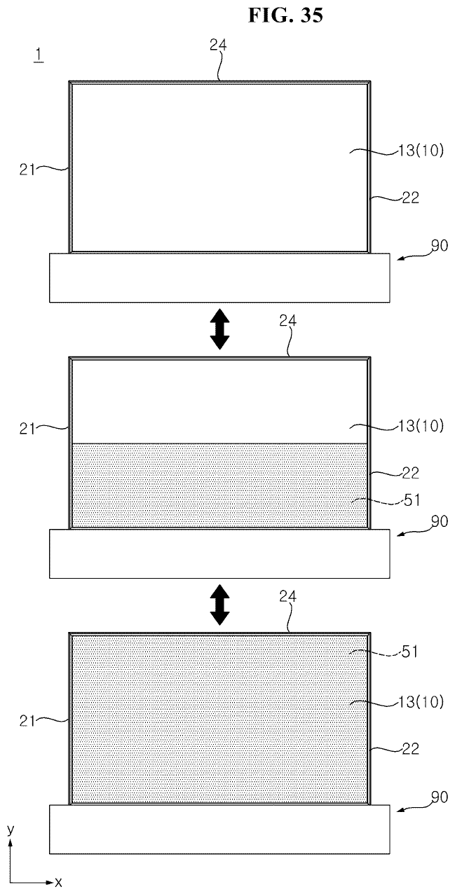

Referring to the upper view of FIG. 35, the cover sheet 51 may not cover the rear of the display 10. This mode may be referred to as a complete light transmitting mode.

Referring to the middle view of FIG. 35, the cover sheet 51 may cover a portion of the rear side of the display 10. This mode may be referred to as a partial light blocking mode or partial light transmitting mode.

Referring to the lower view of FIG. 35, the cover sheet 51 may cover the entire rear side of the display 10. This mode may be referred to as a complete light blocking mode.

The controller C (see FIG. 2) of the display device 1 may switch the display 10 between the light blocking mode and the light transmitting mode by controlling the operation of the driving assembly 30 (see FIG. 2).

Referring to FIGS. 1 to 35, a display device includes: a display panel 11 configured to display an image and having light transparency; a frame 24 located adjacent to a side edge of the display panel 11; a transparent panel 13 facing the display panel 11 and coupled to the frame 24; a light-transmissive back cover 19 opposite the transparent panel 13 with respect to the display panel 11, and facing the display panel 11; and a cover frame 18 fixed to the back cover 19 and coupled to the frame 24.

The display device may further include a fixing member 16 disposed between the transparent panel 13 and the frame 24 and fixed to the transparent panel 13, wherein the fixing member 16 may include a pem-nut elongated along the side edge of the display panel 11 and fixed to the transparent panel 13, the pem-nut protruding from the transparent panel 13 toward the frame 24, wherein the fixing member 16 may be coupled to the frame 24 by the pem-nut.

The cover frame 18 may include a hook 18H elongated along the side edge of the display panel 11, and protruding from the cover frame 18 toward the frame 24, wherein the frame 24 may include a latching portion 24L to which the hook 18H of the cover frame 18 is coupled, the latching portion elongated along the side edge of the display panel 11.

The cover frame 18 may include an alignment rib 18r located adjacent to the hook 18H and protruding from the cover frame 18 toward the frame 24, wherein the frame 24 may include an alignment groove 24h into which the alignment rib 18r is inserted, the alignment groove located adjacent to the latching portion 24L.

The cover frame 18 may further include a support rib 18s protruding from the cover frame 18 toward the frame 24, wherein the frame 24 may further include a side wall by which the support rib 18s is caught.

The display device may further include a side frame 20 fixed to the frame 24 and covering a lateral surface of the transparent panel 13 and the back cover 19.

The frame 24 may cover the side edge of the display panel 11.

The display device may further include: a roller 50 elongated along a first side of the display panel 11 and rotatably coupled to the frame 24; a driving assembly configured to rotate the roller 50; a cover sheet 51 wound around or unwound from the roller 50 to open or close one surface of the display panel 11; and a bar 52 to which one end of the cover sheet 51 is fixed, the bar parallel to the roller 50 and moving between the display panel 11 and the back cover 19.

The display device may further include a guide frame 48 disposed between the frame 24 and the cover frame 18 and coupled to the frame 24, wherein the bar 52 may move while being supported by the guide frame 48.

The guide frame 48 may include: a front guide frame 481 fixed to the frame 24; a rear guide frame 482 parallel to the front guide frame 481 and disposed between the front guide frame 481 and the cover frame 18; and a guide groove 48g connecting the front guide frame 481 and the rear guide frame 482, wherein the bar 52 may be inserted between the front guide frame 481 and the rear guide frame 482.

The driving assembly may include: a motor 31 configured to provide torque; a first gear 34 rotated by receiving the torque from the motor 31; a second gear 35 configured to mesh with the first gear 34 and coupled to a first end of the roller 50; a third gear 36 coupled to a second end of the roller 50; and a fourth gear 37 configured to receive the torque from the motor 31 and to mesh with the third gear 36.

The driving assembly may include: a first reel 40P coupled to a shaft of the first gear 34; a first connection member 40a unwound from or wound around the first reel 40P and having one end fixed to the bar 52; a second reel 40Q coupled to a shaft of the fourth gear 37; and a second connection member 40b unwound from or wound around the second reel 40Q and having one end fixed to the bar 52.

The driving assembly may include: a first upper pulley 42a coupled to the frame 24 and adjacent to a second side of the display panel 11 that is opposite the first side thereof, with an outer circumference of the first upper pulley being in contact with the first connection member 40a; and a second upper pulley 42b coupled to the frame 24 and adjacent to the second side of the display panel 11, the second upper pulley spaced apart from the first upper pulley 42a along the second side of the display panel 11, with an outer circumference of the second upper pulley being in contact with the second connection member 40b.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

The foregoing embodiments are merely examples and are not to be considered as limiting the present disclosure. The scope of the present disclosure should be determined by rational interpretation of the appended claims, and all modifications within the equivalents of the disclosure are intended to be included within the scope of the present disclosure.

1. A display device comprising:
a display panel configured to display an image and having light transparency;
a frame located adjacent to a side edge of the display panel;
a transparent panel facing the display panel and coupled to the frame;
a light-transmissive back cover opposite the transparent panel with respect to the display panel, and facing the display panel; and
a cover frame fixed to the back cover and coupled to the frame.

2. The display device of claim 1, further including a fixing member disposed between the transparent panel and the frame and fixed to the transparent panel,
wherein the fixing member comprises a pem-nut elongated along the side edge of the display panel and fixed to the transparent panel, the pem-nut protruding from the transparent panel toward the frame,
wherein the fixing member is coupled to the frame by the pem-nut.

3. The display device of claim 1, wherein the cover frame comprises a hook elongated along the side edge of the display panel, and protruding from the cover frame toward the frame,
wherein the frame comprises a latching portion to which the hook of the cover frame is coupled, the latching portion elongated along the side edge of the display panel.

4. The display device of claim 3, wherein the cover frame comprises an alignment rib located adjacent to the hook and protruding from the cover frame toward the frame,
wherein the frame comprises an alignment groove into which the alignment rib is inserted, the alignment groove located adjacent to the latching portion.

5. The display device of claim 4, wherein the cover frame further comprises a support rib protruding from the cover frame toward the frame,
wherein the frame further comprises a side wall by which the support rib is caught.

6. The display device of claim 1, further comprising a side frame fixed to the frame and covering a lateral surface of the transparent panel and the back cover.

7. The display device of claim 1, wherein the frame covers the side edge of the display panel.

8. The display device of claim 1, further comprising:
a roller elongated along a first side of the display panel and rotatably coupled to the frame;
a driving assembly configured to rotate the roller;
a cover sheet wound around or unwound from the roller to open or close one surface of the display panel; and
a bar to which one end of the cover sheet is fixed, the bar parallel to the roller and moving between the display panel and the back cover.

9. The display device of claim 8, further comprising a guide frame disposed between the frame and the cover frame and coupled to the frame,
wherein the bar moves while being supported by the guide frame.

10. The display device of claim 9, wherein the guide frame comprises:
a front guide frame fixed to the frame;
a rear guide frame parallel to the front guide frame and disposed between the front guide frame and the cover frame; and
a guide groove connecting the front guide frame and the rear guide frame,
wherein the bar is inserted between the front guide frame and the rear guide frame.

11. The display device of claim 8, wherein the driving assembly comprises:
a motor configured to provide torque;
a first gear rotated by receiving the torque from the motor;
a second gear configured to mesh with the first gear and coupled to a first end of the roller;
a third gear coupled to a second end of the roller; and
a fourth gear configured to receive the torque from the motor and to mesh with the third gear.

12. The display device of claim 11, wherein the driving assembly comprises:
a first reel coupled to a shaft of the first gear;
a first connection member unwound from or wound around the first reel and having one end fixed to the bar;
a second reel coupled to a shaft of the fourth gear; and
a second connection member unwound from or wound around the second reel and having one end fixed to the bar.

13. The display device of claim 12, wherein the driving assembly comprises:
a first upper pulley coupled to the frame and adjacent to a second side of the display panel that is opposite the first side thereof, with an outer circumference of the first upper pulley being in contact with the first connection member; and
a second upper pulley coupled to the frame and adjacent to the second side of the display panel, the second upper pulley spaced apart from the first upper pulley along the second side of the display panel, with an outer circumference of the second upper pulley being in contact with the second connection member.
